(19) United States
(12) Patent Application Publication
(10) Pub. No.: US 2026/0047158 A1
(43) Pub. Date: Feb. 12, 2026

(54) SEMICONDUCTOR DEVICE

(71) Applicant: Samsung Electronics Co., Ltd., Suwon-si (KR)

(72) Inventors: Yunyeong YI, Suwon-si (KR); Myung Gil KANG, Suwon-si (KR); Wookhyun KWON, Suwon-si (KR); Younggwon KIM, Suwon-si (KR); Jong Pil KIM, Suwon-si (KR); Soojin JEONG, Bucheon-si (KR); Byoung Hak HONG, Suwon-si (KR)

(73) Assignee: Samsung Electronics Co., Ltd., Suwon-si (KR)

(21) Appl. No.: 19/014,999

(22) Filed: Jan. 9, 2025

(30) Foreign Application Priority Data
Aug. 12, 2024 (KR) 10-2024-0107481

(51) Int. Cl. H10D 62/13; H10D 30/00; H10D 30/01; H10D 30/43; H10D 62/10; H10D 62/60; H10D 62/83; H10D 62/832; H10D 64/23; H10D 64/62; H10D 84/01; H10D 84/83

(52) U.S. Cl. CPC H10D 62/151; H10D 30/014; H10D 30/0194; H10D 30/43; H10D 30/503; H10D 30/506; H10D 62/121; H10D 62/60; H10D 62/83; H10D 62/832; H10D 64/251; H10D 64/62; H10D 84/0128; H10D 84/013; H10D 84/0149; H10D 84/8311; H10D 84/8312; H10D 84/832

(57) ABSTRACT

A semiconductor device may include a substrate, a first source/drain pattern and a second source/drain pattern spaced apart in a first direction on the substrate, a height from an upper surface of a central portion of the first source/drain pattern to an upper surface of the substrate in a vertical direction is lower than a height from an upper surface of an edge of the first source/drain pattern to the upper surface of the substrate, a plurality of channel patterns connecting between the first source/drain pattern and the second source/drain pattern, and the plurality of channel patterns stacked to be spaced apart from each other, a gate structure surrounding the plurality of channel patterns and extending in a second direction, and a contact plug extending in the vertical direction from an upper surface of the first source/drain pattern, and the contact plug connected to the first source/drain pattern.

### CROSS-REFERENCE TO RELATED APPLICATION

This application claims priority to and the benefit of Korean Patent Application No. 10-2024-0107481 filed in the Korean Intellectual Property Office on Aug. 12, 2024, the entire contents of which is incorporated herein by reference.

### BACKGROUND

Some example embodiments relate to a semiconductor device.

A semiconductor is a material belonging to an intermediate region between a conductor and an insulator, and refers to a material that conducts electricity under a desired (and/or alternatively predetermined) condition. Various semiconductor devices may be manufactured by using such a semiconductor material. For example, a memory device and the like may be manufactured using a semiconductor material. Such a semiconductor device may be used in various electronic devices.

In logic devices, contact plug structures may be formed to connect gate structures, source/drain layers, and upper wires to apply electrical signals to them, respectively. However, when the gate structure and the source/drain layer are not in good contact with the contact plug structure, signals may not be sufficiently transferred from the upper wires to the gate structure and the source/drain layer, therefore, a contact resistance between them may be increased.

Accordingly, various methods to decrease the contact resistance between the source/drain layer and the contact plug structure are being researched.

### SUMMARY

Some example embodiments of the present disclosure attempt to provide a semiconductor device having improved characteristics.

According to some example embodiments, a semiconductor device may include a substrate, a first source/drain pattern and second source/drain pattern spaced apart in a first direction on the substrate, a height from an upper surface of a central portion of the first source/drain pattern to an upper surface of the substrate in a vertical direction is lower than a height from an upper surface of an edge of the first source/drain pattern to the upper surface of the substrate in the vertical direction, the vertical direction being a direction perpendicular to the upper surface of the substrate, a plurality of channel patterns connecting between the first source/drain pattern and the second source/drain pattern, and the plurality of channel patterns stacked to be spaced apart from each other, a gate structure surrounding the plurality of channel patterns and extending in a second direction, the second direction crossing the first direction, and a contact plug extending in a vertical direction from an upper surface of the first source/drain pattern, and the contact plug connected to the first source/drain pattern. The first source/drain pattern comprises a first source/drain layer adjacent to the gate structure, a second source/drain layer on the first source/drain layer, and the second source/drain layer comprising first conductivity type impurities, and a bottom level of the second source/drain layer is lower than a bottom level of the contact plug.

According to some example embodiments, a semiconductor device may include a substrate comprising a first region and a second region, a first source/drain pattern and a second source/drain pattern spaced apart in a first direction on the first region of the substrate, a height from an upper surface of a central portion of the first source/drain pattern to an upper surface of the substrate in a vertical direction is higher than, or a same height as, a height from an upper surface of an edge of the first source/drain pattern to the upper surface of the substrate in the vertical direction, the vertical direction being a direction perpendicular to the upper surface of the substrate, a plurality of first channel patterns connecting between the first source/drain pattern and the second source/drain pattern, and the plurality of first channel patterns stacked to be spaced apart from each other, a first gate structure surrounding the plurality of first channel patterns and extending in a second direction, the second direction crossing the first direction, a first contact plug extending in a vertical direction, the first contact plug penetrating an upper surface of the first source/drain pattern by a first depth, the first depth being a distance from an upper surface of the first source/drain pattern to a bottom surface of the first contact plug, and the first contact plug connected to the first source/drain pattern, a third source/drain pattern and a fourth source/drain pattern spaced apart in the first direction on the second region of the substrate, a height from an upper surface of a central portion of the third source/drain pattern in a vertical direction is lower than a height from the upper surface of an edge of the third source/drain pattern to the upper surface of the substrate in the vertical direction, a plurality of second channel patterns connecting between the third source/drain pattern and the fourth source/drain pattern, and the plurality of second channel patterns stacked to be spaced apart from each other, a second gate structure surrounding the second channel patterns and extending in the second direction, and a second contact plug extending in a vertical direction the second contact plug penetrating from an upper surface of the third source/drain pattern by a second depth, the second depth being a distance from an upper surface of the third source/drain pattern to a bottom surface of the second contact plug, and the second contact plug connected to the third source/drain pattern. The second depth is greater than the first depth, the third source/drain pattern comprises a first source/drain layer adjacent to the second gate structure, a second source/drain layer on the first source/drain layer, and the second source/drain layer comprising first conductivity type impurities, a bottom level of the second source/drain layer is lower than a bottom level of the second contact plug.

According to some example embodiments, a semiconductor device may include a substrate, a first source/drain pattern and a second source/drain pattern spaced apart in a first direction on the substrate, a height from an upper surface of a central portion of the first source/drain pattern to an upper surface of the substrate in a vertical direction is higher than, or a same height as, a height from an upper surface of an edge of the first source/drain pattern to the upper surface of the substrate in the vertical direction, the vertical direction being a direction perpendicular to the upper surface of the substrate, a plurality of channel patterns connecting between the first source/drain pattern and the second source/drain pattern, and the plurality of channel patterns stacked to be spaced apart from each other, a gate structure surrounding the plurality of channel patterns and extending in a second direction, the second direction crossing the first direction, and the gate structure having a threshold length, and a contact plug extending in a vertical direction from an upper surface of the first source/drain pattern, and the contact plug connected to the first source/drain pattern. The first source/drain pattern comprise a first source/drain layer adjacent to the gate structure, and a second source/drain layer on the first source/drain layer, and the second source/drain layer comprising first conductivity type impurities, a bottom level of the second source/drain layer is lower than a bottom level of the contact plug.

According to some example embodiments, the performance of transistors having different channel types may be improved.

### BRIEF DESCRIPTION OF THE DRAWINGS

FIG. 1 is a top plan view showing a semiconductor device according to some example embodiments.

FIG. 2 is a cross-sectional view taken along lines A-A′ and B-B′ of FIG. 1 according to some example embodiments.

FIG. 3 is a cross-sectional view taken along lines A-A′ and B-B′ of FIG. 1 according to some example embodiments.

FIG. 4 is a cross-sectional view taken along lines A-A′ and B-B′ of FIG. 1 according to some example embodiments.

FIG. 5 is a cross-sectional view taken along lines A-A′ and B-B′ of FIG. 1 according to some example embodiments.

FIG. 6 to FIG. 18 are cross-sectional views for explaining a manufacturing method of a semiconductor device according to some example embodiments.

### DETAILED DESCRIPTION

Hereinafter, with reference to accompanying drawings, various example embodiments will be described in detail such that a person of an ordinary skill may easily practice them in the technical field to which the present disclosure belongs. The present disclosure may be embodied in many different forms and is not limited to the example embodiments described herein.

In order to clearly explain the example embodiments of the present disclosure, parts irrelevant to the description have been omitted, and the same reference numerals should be attached to the same or similar constituent elements throughout the specification.

In addition, since the size and thickness of each component shown in the drawing is arbitrarily shown for convenience of description, the present disclosure is not necessarily limited to as shown. In the drawings, the thickness of layers, films, panels, regions, etc., are exaggerated for clarity. In the drawings, the thickness of some layers and regions may be exaggerated for ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to mean positioned above or below the target element, and will not necessarily be understood to mean positioned “at an upper side” based on an opposite to gravity direction.

In addition, unless explicitly described to the contrary, the word “comprise,” and variations such as “comprises” or “comprising,” will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, throughout the specification, two directions parallel to an upper surface of a substrate and crossing each other may be defined as a first direction DR1 and a second direction DR2, respectively, and a direction perpendicular to the upper surface of the substrate may be referred to as a third direction DR3. For example, the first direction DR1 and the second direction DR2 may be orthogonal to each other.

The drawings for a semiconductor device according to some example embodiments illustrate, transistors including nanosheets, Multi-Bridge-Channel Field Effect Transistor (MBCFET™), as an example, but example embodiments are not limited thereto. A semiconductor device according to some example embodiments may include a transistor including a nanowire, a fin-type transistor (FinFET) including a channel region of a fin-type pattern shape, a tunneling transistor (tunneling FET), a 3D stacked field-effect transistor (3DSFET), a CFET (Complementary Field Effect Transistor), or the like.

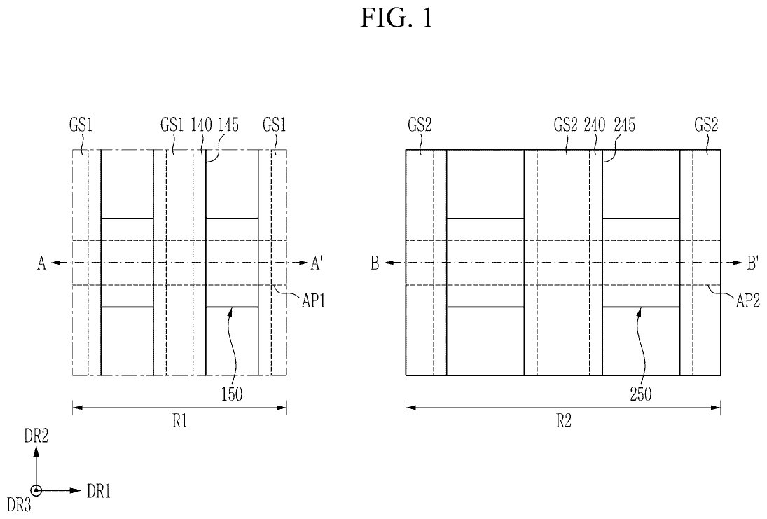

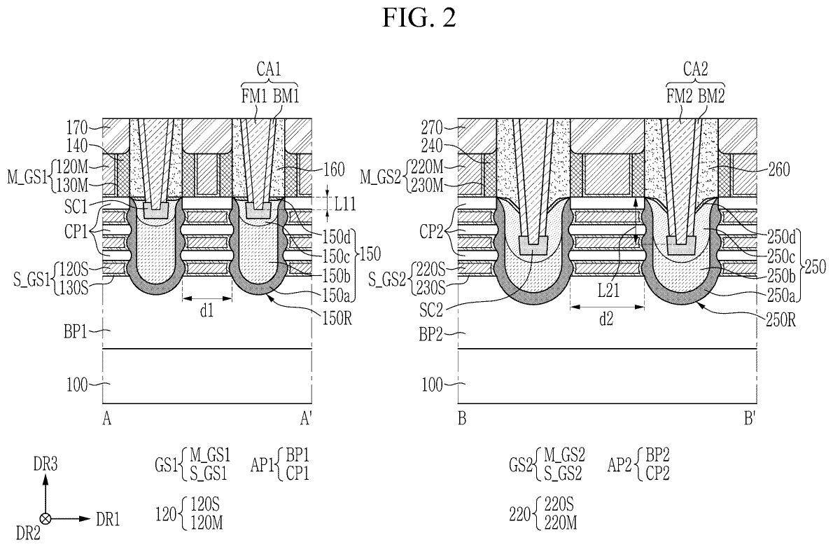

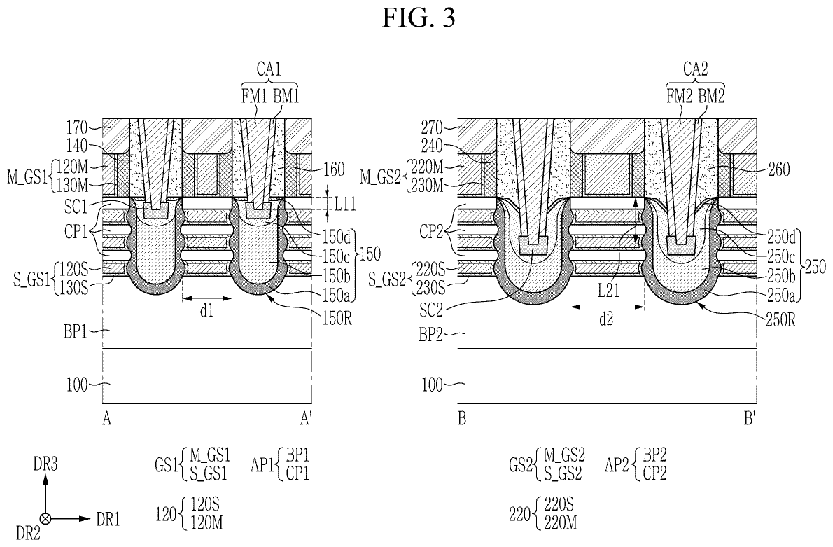

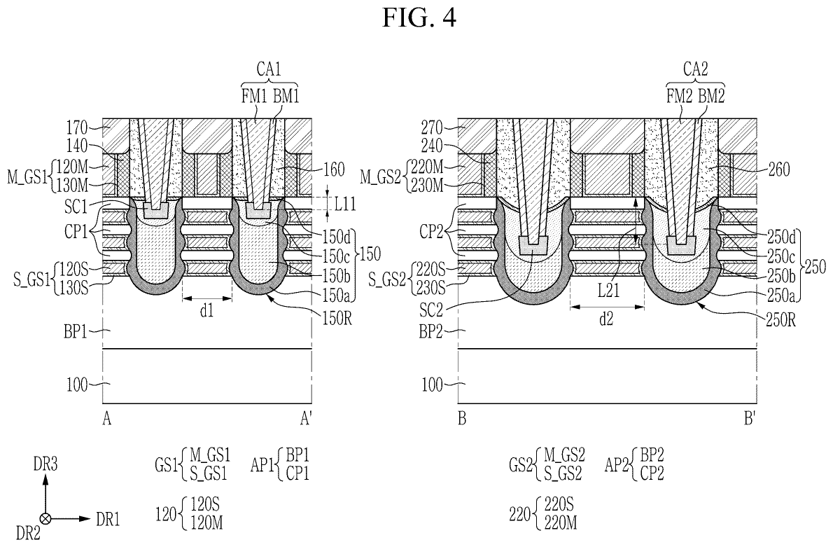

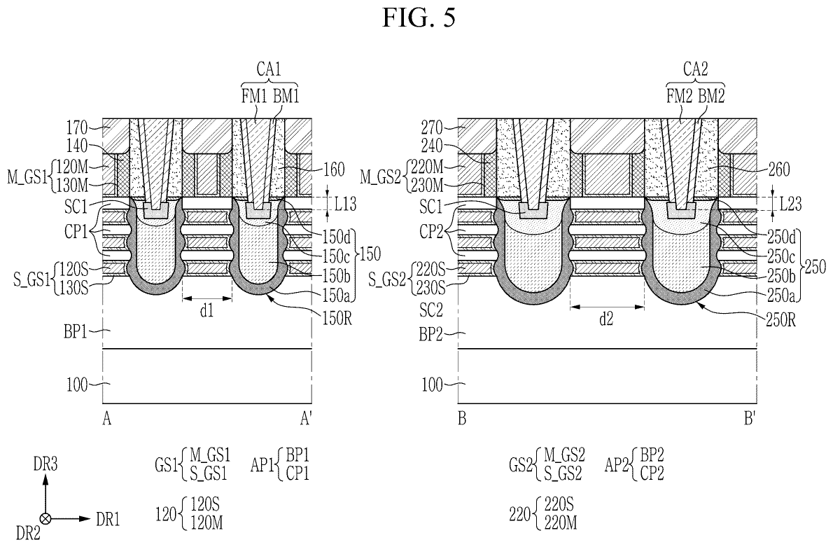

FIG. 1 is a top plan view showing a semiconductor device according to some example embodiments. FIG. 2 is a cross-sectional view taken along lines A-A′ and B-B′ of FIG. 1. FIG. 3 is a cross-sectional view taken along lines A-A′ and B-B′ of FIG. 1 according to some example embodiments. FIG. 4 is a cross-sectional view taken along lines A-A′ and B-B′ of FIG. 1 according to some example embodiments. FIG. 5 is a cross-sectional view taken along lines A-A′ and B-B′ of FIG. 1 according to some example embodiments.

Referring to FIG. 1 to FIG. 5, a semiconductor device according to some example embodiments may include a substrate 100 having a first region R1 and a second region R2.

According to some example embodiments, a semiconductor device may include first and second active patterns AP1 and AP2, first and second gate structures GS1 and GS2, first and second source/drain patterns 150 and 250 and first and second contact plugs CA1 and CA2, formed on the substrate 100.

According to some example embodiments, the substrate 100 may be a silicon-on-insulator (SOI) or bulk silicon. Alternatively, the substrate 100 may be a silicon substrate, or may include another material, for example, silicon germanium (SiGe), silicon-germanium-on-insulator (SGOI), indium antimonide, lead tellurium compound, indium arsenic, indium phosphide, gallium arsenide or gallium antimonide, but example embodiments are not limited thereto. Depending on the example embodiments, the substrate 100 may be formed of an insulating substrate including an insulating material.

According to some example embodiments, the first region R1 and the second region R2 may be a logic cell region in which logic transistors forming the logic circuit of the semiconductor device are disposed. According to some example embodiments, logic transistors forming the logic circuit may be disposed on the logic cell region of the substrate 100. The first region R1 and the second region R2 may include a portion of the logic transistors.

According to some example embodiments, the first region R1 and the second region R2 may be regions having different electric characteristics. The first region R1 and the second region R2 may be regions including transistors having channels of different lengths. The first region R1 may be a single-channel region in which transistors having channels of relatively short lengths are formed, and the second region R2 may be a long-channel region in which transistors having channels of relatively long lengths are formed.

In the drawings, as a mere example, it is illustrated that first and second regions R1 and R2 of the substrate 100 are disposed along the first direction DR1, but the example embodiments of the present disclosure is not limited thereto, and the first and second regions R1 and R2 of the substrate 100 may be disposed along the second direction DR2.

According to some example embodiments, the transistor included in the first region R1 and the transistor included in the second region R2 may have structures generally similar to each other.

However, a bottom surface level of a first contact plug CA1 included in the transistor included in the first region R1 and a bottom surface level of a second contact plug CA2 included in the transistor included in the second region R2 may be different from each other. For example, as shown in FIG. 2 to FIG. 4, the bottom surface level of the first contact plug CA1 may be higher than the bottom surface level of the second contact plug CA2.

However, example embodiments are not limited thereto, and as shown in FIG. 5, the bottom surface level of the first contact plug CA1 may be similar to or the same as the bottom surface level of the second contact plug CA2.

Details related to this will be described later with reference to FIG. 2 to FIG. 5.

In addition, a shape of an upper surface of the first source/drain pattern 150 included in the transistor included in the first region R1 and a shape of an upper surface of the second source/drain pattern 250 included in the transistor included in the second region R2 may be different from each other. For example, as shown in FIG. 2 to FIG. 4, the upper surface of the first source/drain pattern 150 may have a generally flat shape, and the upper surface of the second source/drain pattern 250 may have a concave shape.

However, example embodiments are not limited thereto, and as shown in FIG. 5, a shape of the upper surface of the first source/drain pattern 150 may be similar to or the same as the shape of the upper surface of the second source/drain pattern 250.

Details related to this will be described later with reference to FIG. 2 to FIG. 5.

In addition, a first length d1 of a first sub-gate structure S_GS1 along the first direction DR1 included in the transistor included in the first region R1 may be different from a second length d2 along the first direction DR1 of a second sub-gate structure S_GS2 included in the transistor included in the second region R2. For example, as shown in FIG. 2 to FIG. 5, the second length d2 of the second sub-gate structure S_GS2 along the first direction DR1 may be greater than the first length d1 along the first direction DR1 of the first sub-gate structure S_GS1.

Details related to this will be described later with reference to FIG. 2 to FIG. 5.

According to some example embodiments, a semiconductor device may include first and second channel patterns CP1 and CP2 located on the first region R1 and the second region R2 of the substrate 100, respectively, the first and second gate structures GS1 and GS2 surrounding the first and second channel patterns CP1 and CP2, the first and second source/drain patterns 150 and 250 connected to both sides of the first and second channel patterns CP1 and CP2, and the first and second contact plugs CA1 and CA2 connected to the first and second source/drain patterns 150 and 250.

According to some example embodiments, the first and second active patterns AP1 and AP2 may be located on the first region R1 and the second region R2 of the substrate 100, respectively. In some example embodiments, the first and second active patterns AP1 and AP2 may be located in a region where PMOS is formed, but example embodiments are not limited thereto.

According to some example embodiments, the first and second active patterns AP1 and AP2 may be a multi-channel active pattern. The first and second active patterns AP1 and AP2 may include first and second bottom patterns BP1 and BP2, and pluralities of the first and second channel patterns CP1 and CP2, respectively.

The first and second bottom patterns BP1 and BP2 may be located on the first and second regions R1 and R2 of the substrate 100, respectively. According to some example embodiments, the first and second bottom patterns BP1 and BP2 may be portions protruding from the substrate 100 in the third direction DR3. The first and second bottom patterns BP1 and BP2 may extend in the first direction DR1.

According to some example embodiments, the pluralities of the first and second channel patterns CP1 and CP2 may have a nanosheet shape, and may be a semiconductor pattern including a semiconductor material.

According to some example embodiments, the pluralities of the first and second channel patterns CP1 and CP2 may be located on an upper surface of the first and second bottom patterns BP1 and BP2, respectively. The pluralities of the first and second channel patterns CP1 and CP2 may be spaced apart from the first and second bottom patterns BP1 and BP2 in the third direction DR3, respectively. Each of the pluralities of the first and second channel patterns CP1 and CP2 may be spaced apart from each other in the third direction DR3. Here, the third direction DR3 may be a direction crossing the first direction DR1 and the second direction DR2. For example, the third direction DR3 may be a vertical direction perpendicular to an upper surface of the substrate 100. The second direction DR2 may be a direction crossing the first direction DR1. For example, the second direction DR2 may be a direction perpendicularly crossing the first direction DR1.

FIG. 2 to FIG. 5 illustrate three first channel patterns CP1 and three second channel patterns CP2 are stacked to be spaced apart along the third direction DR3, but this is merely for better understanding and ease of description, and example embodiments are not limited thereto. For example, four first and second channel patterns CP1 and CP2 may be stacked to be spaced apart along the third direction DR3.

The first and second bottom patterns BP1 and BP2 may be formed by etching a portion of the substrate 100, and may include an epitaxial layer grown from the substrate 100. The first and second bottom patterns BP1 and BP2 may include an elemental semiconductor material such as silicon (Si) or germanium (Ge). However, example embodiments are not limited thereto. In addition, the first and second bottom patterns BP1 and BP2 may include a compound semiconductor, and for example, may include a group IV-IV compound semiconductor or a group Ill-V compound semiconductor.

The group IV-IV compound semiconductor may be, for example, a binary compound or a ternary compound including at least two or more among carbon(C), silicon (Si), germanium (Ge), and tin (Sn). However, example embodiments are not limited thereto.

The group III-V compound semiconductor may be, for example, a binary compound, a ternary compound, or a quaternary compound, formed by combining at least one of aluminum (AI), gallium (Ga) and indium (In), which are group III elements, with one of phosphorus (P), arsenic (As) and antimony (Sb), which are group V elements.

However, example embodiments are not limited thereto, and depending on cases, the first and second bottom patterns BP1 and BP2 may be formed of an insulation pattern including an insulating material.

The pluralities of the first and second channel patterns CP1 and CP2 may include one of silicon (Si) or silicon germanium (SiGe), which is an elemental semiconductor material, a group IV-IV compound semiconductor, or a group Ill-V compound semiconductor. Each of the pluralities of the first and second channel patterns CP1 and CP2 may include the same material as the first and second bottom patterns BP1 and BP2, and may include a material different from the first and second bottom patterns BP1 and BP2.

For example, the first and second bottom patterns BP1 and BP2 and the pluralities of the first and second channel patterns CP1 and CP2 may include silicon (Si). As another example, the first and second bottom patterns BP1 and BP2 and the pluralities of the first and second channel patterns CP1 and CP2 may include silicon germanium (SiGe). As a still another example, the first and second bottom patterns BP1 and BP2 may include silicon (Si), and the pluralities of the first and second channel patterns CP1 and CP2 may include silicon germanium (SiGe).

According to some example embodiments, the first and second gate structures GS1 and GS2 may be located on the first and second bottom patterns BP1 and BP2, respectively. The first and second gate structures GS1 and GS2 may cross the first and second bottom patterns BP1 and BP2. The first gate structure GS1 may surround each of the plurality of first channel patterns CP1. The second gate structure GS2 may surround each of the plurality of second channel patterns CP2. The first and second gate structures GS1 and GS2 may extend in the second direction DR2. The first gate structures GS1 may be located to be spaced apart in the first direction DR1. The second gate structures GS2 may be located to be spaced apart in the first direction DR1.

According to some example embodiments, the first gate structure GS1 may include a plurality of first sub-gate structures S_GS1 and a first main gate structure M_GS1. According to some example embodiments, the second gate structure GS2 may include a plurality of second sub-gate structures S_GS2 and a second main gate structure M_GS2. The plurality of first sub-gate structures S_GS1 may be located between the plurality of first channel patterns CP1 adjacent in the third direction DR3 and between the first bottom pattern BP1 and the first channel pattern CP1 located at a lowermost position. In the same way, the plurality of second sub-gate structures S_GS2 may be located between the plurality of second channel patterns CP2 adjacent in the third direction DR3 and between the second bottom pattern BP2 and the second channel pattern CP2 located at a lowermost position. The first and second main gate structures M_GS1 and M_GS2 may be located on the first and second channel patterns CP1 and CP2 located in an uppermost portion, respectively.

In more detail, the plurality of first sub-gate structures S_GS1 may be located between an upper surface of the first bottom pattern BP1 and a lower surface of a lowermost first channel pattern CP1, and between an upper surface of the first channel pattern CP1 and a lower surface of the first channel pattern CP1 facing each other in the third direction DR3. The plurality of second sub-gate structures S_GS2 may be located between an upper surface of the second bottom pattern BP2 and a lower surface of a lowermost second channel pattern CP2, and between an upper surface of the second channel pattern CP2 and a lower surface of the second channel pattern CP2 facing each other in the third direction DR3.

Pluralities of first and second sub-gate structures S_GS1 and S_GS2 may be adjacent to the first and second source/drain patterns 150 and 250, respectively. The first and second main gate structures M_GS1 and M_GS2 may be located on the pluralities of first and second sub-gate structures S_GS1 and S_GS2 and the first and second channel patterns CP1 and CP2, respectively.

According to some example embodiments, the first and second active patterns AP1 and AP2 may include the pluralities of the first and second channel patterns CP1 and CP2, respectively. According to some example embodiments, the first and second gate structures GS1 and GS2 may include the pluralities of first and second sub-gate structures S_GS1 and S_GS2, respectively. At this time, the number of the pluralities of first and second sub-gate structures S_GS1 and S_GS2 may be proportional to the number of the pluralities of the first and second channel patterns CP1 and CP2 included in the first and second active patterns AP1 and AP2, respectively. For example, the number of the pluralities of first and second sub-gate structures S_GS1 and S_GS2 may be the same as the number of the pluralities of the first and second channel patterns CP1 and CP2, respectively. For example, as shown in FIG. 2 to FIG. 5, the number of the pluralities of first and second sub-gate structures S_GS1 and S_GS2 may be 3. However, example embodiments are not limited thereto, the number of the pluralities of first and second sub-gate structures S_GS1 and S_GS2 may be two, respectively, and may be four or more.

Each of the plurality of first sub-gate structures S_GS1 may include a first sub-gate electrode 120S and a first sub-gate insulation layer 130S. Each of the plurality of second sub-gate structures S_GS2 may include a second sub-gate electrode 220S and a second sub-interface insulation layer 230S.

First and second gate electrodes 120 and 220 may be formed on the first and second bottom patterns BP1 and BP2, respectively. The first and second gate electrodes 120 and 220 may cross the first and second bottom patterns BP1 and BP2. The first and second gate electrodes 120 and 220 may surround the pluralities of the first and second channel patterns CP1 and CP2.

At least a portion of the first and second gate electrodes 120 and 220 may be located on the stacking structure of the pluralities of the first and second channel patterns CP1 and CP2. Another portion of the first and second gate electrodes 120 and 220 may be formed to cover both side surfaces of the stacking structure of the pluralities of the first and second channel patterns CP1 and CP2. At this time, 4 surfaces of the pluralities of the first and second channel patterns CP1 and CP2 may be surrounded by the first and second gate electrodes 120 and 220.

The first and second gate electrodes 120 and 220 may include at least one of a metal, a metal alloy, a conductive metal nitride, a metal silicide, a doped semiconductor material, a conductive metal oxide, and a conductive metal nitride oxide. The first and second gate electrodes 120 and 220 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAI), titanium aluminum carbonitride (TiAIC-N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), Zinc (Zn), vanadium (V), and a combination thereof, but example embodiments are not limited thereto. The conductive metal oxide and the conductive metal nitride oxide may include, but are not limited to, oxidized forms of the materials described above.

According to some example embodiments, first and second sub-gate insulation layers 130S and 230S may surround first and second sub-gate electrodes 120S and 220S, respectively. The first and second sub-gate insulation layers 130S and 230S may be located on the first and second channel patterns CP1 and CP2, respectively. For example, the first and second sub-gate insulation layers 130S and 230S may directly contact the first and second channel patterns CP1 and CP2, respectively. For example, the first and second sub-gate insulation layers 130S and 230S may include silicon oxide, silicon oxidation nitride or silicon nitride. However, example embodiments are not limited thereto. Alternatively, for example, the first and second sub-gate insulation layers 130S and 230S may include a high dielectric constant material. Alternatively, for example, the first and second sub-gate insulation layers 130S and 230S may include both of a silicon oxide and a high dielectric constant material. The high dielectric constant material may include a material having a dielectric constant higher than silicon oxide (SiO₂), such as hafnium oxide (HfO), aluminum oxide (AIO) or tantalum oxide (TaO).

Meanwhile, although not shown, a first inner spacer may be interposed between the first sub-gate electrodes 120S and the first source/drain pattern 150. The first inner spacer may directly contact the first source/drain pattern 150. The first sub-gate electrodes 120S may be spaced apart from the first source/drain pattern 150 by the first inner spacer. In the same way, a second inner spacer may be interposed between the second sub-gate electrodes 220S and the second source/drain pattern 250. The second inner spacer may directly contact the second source/drain pattern 250. The second sub-gate electrodes 220S may be spaced apart from the second source/drain pattern 250 by the second inner spacer.

According to some example embodiments, the first length d1 of the first sub-gate structure S_GS1 along the first direction DR1 may be smaller than the second length d2 of the second sub-gate structure S_GS2 along the first direction DR1, and accordingly, a length of the first channel pattern CP1 may be smaller than a length of the second channel pattern CP2. The first length d1 may lie within a first range of a first threshold length. For example, the first length d1 may lie within a range of about 0 nm to about 20 nm. The second length d2 may lie within a second range of a second threshold length. For example, the second length d2 may lie within a range of about 20 nm to about 300 nm.

The first and second main gate structures M_GS1 and M_GS2 may be located on the first and second sub-gate structures S_GS1 and S_GS2 and the pluralities of the first and second channel patterns CP1 and CP2, respectively. The first and second main gate structures M_GS1 and M_GS2 may be located on upper surfaces of the pluralities of the first and second channel patterns CP1 and CP2.

The first and second main gate structures M_GS1 and M_GS2 may include first and second main gate electrodes 120M and 220M and first and second main gate insulation layers 130M and 230M, respectively.

The first and second main gate electrodes 120M and 220M may be located on the first and second sub-gate structures S_GS1 and S_GS2 and the pluralities of the first and second channel patterns CP1 and CP2, respectively. The first and second main gate electrodes 120M and 220M may be located on the upper surfaces of the pluralities of the first and second channel patterns CP1 and CP2. The first and second main gate electrodes 120M and 220M may include the same material as the first and second sub-gate electrodes 120S and 220S. For example, the first and second main gate electrodes 120M and 220M may include at least one of a metal, a metal alloy, a conductive metal nitride, a metal silicide, a doped semiconductor material, a conductive metal oxide, and a conductive metal nitride oxide. However, example embodiments are not limited thereto.

The first and second main gate insulation layers 130M and 230M may extend along a side surface and a lower surface of the first and second main gate electrodes 120M and 220M. The first and second main gate insulation layers 130M and 230M may extend along a side surface of first and second gate spacers 140 and 240. For example, the first and second main gate insulation layers 130M and 230M may include silicon oxide, silicon oxidation nitride or silicon nitride. Alternatively, for example, the first and second main gate insulation layers 130M and 230M may include a high dielectric constant material. Alternatively, for example, the first and second main gate insulation layers 130M and 230M may include both of a silicon oxide and a high dielectric constant material. The high dielectric constant material may include a material having a dielectric constant higher than silicon oxide (SiO₂), such as hafnium oxide (HfO), aluminum oxide (AIO) or tantalum oxide (TaO). However, example embodiments are not limited thereto.

A semiconductor device according to some example embodiments may further include the first and second gate spacers 140 and 240, first and second interlayer insulating layers 160 and 260 and first and second capping layers 170 and 270, respectively, in the first region R1 and the second region R2.

According to some example embodiments, a first gate spacer 140 may be located on a side surface of a first main gate electrode 120M. Specifically, a pair of first gate spacers 140 may be located on both sides of the first main gate electrode 120M. According to some example embodiments, a second gate spacer 240 may be located on a side surface of a second main gate electrode 220M. Specifically, a pair of second gate spacers 240 may be located on both sides of the second main gate electrode 220M.

According to some example embodiments, the first gate spacer 140 may not be disposed between the first bottom pattern BP1 and the plurality of first channel patterns CP1. The first gate spacer 140 may not be disposed between the plurality of first channel patterns CP1 that are adjacent in the third direction DR3. According to some example embodiments, the second gate spacer 240 may not be disposed between the second bottom pattern BP2 and the plurality of second channel patterns CP2. The second gate spacer 240 may not be disposed between the plurality of second channel patterns CP2 that are adjacent in the third direction DR3.

According to some example embodiments, the first and second gate spacers 140 and 240 may include, for example, at least one of silicon nitride (SiN), silicon nitride oxide (SiON), silicon oxide (SiO₂), silicon carbonate nitride (SiOCN), silicon boronnitride (SiBN), silicon oxyboronitride (SiOBN), silicon oxycarbide (SiOC), and combination thereof. However, example embodiments are not limited thereto. Although the first and second gate spacers 140 and 240 are illustrated as single layers, it is merely for better understanding and ease of description, and example embodiments are not limited thereto.

According to some example embodiments, the first and second interlayer insulating layers 160 and 260 may be located on the first and second source/drain patterns 150 and 250, respectively. The first and second interlayer insulating layers 160 and 260 may not cover an upper surface of the first and second capping layers 170 and 270.

For example, the first and second interlayer insulating layers 160 and 260 may include at least one of silicon oxide (SiO₂), silicon nitride (SiN), silicon nitride oxide (SiON), or low dielectric constant material. Low dielectric constant material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen Silazen (TOSZ), fluorosilicate glass (FSG), polyimide nanofoams such as polypropylene oxide, carbon-doped silicon oxide (CDO), OSG (Organo silicate glass), SiLK, amorphous fluorinated carbon, silica aerogels, silica xerogels, mesoporous silica, or a combination thereof, but example embodiments are not limited thereto.

According to some example embodiments, the first and second capping layers 170 and 270 may be located on the first and second main gate structures M_GS1 and M_GS2, respectively. The first and second capping layers 170 and 270 may be located on the first and second main gate structures M_GS1 and M_GS2 and the first and second gate spacers 140 and 240.

According to some example embodiments, the upper surface of the first and second capping layers 170 and 270 may be disposed at the same level as an upper surface of the first and second interlayer insulating layers 160 and 260.

For example, the first and second capping layers 170 and 270 may include silicon nitride (SiN), silicon nitride oxide (SiON), silicon (Si) carbonitride (SiCN), silicon carbonate nitride (SiOCN), or a combination thereof. However, example embodiments are not limited thereto. The first and second capping layers 170 and 270 may include a material having an etch selectivity with respect to the first and second interlayer insulating layers 160 and 260.

According to some example embodiments, the first and second source/drain patterns 150 and 250 may be located on both sides of the first and second sub-gate structures S_GS1 and S_GS2, respectively. The first and second source/drain patterns 150 and 250 may be in contact with a side surface of the first and second channel patterns CP1 and CP2 and a side surface of the first and second sub-gate structures S_GS1 and S_GS2, respectively. The first and second source/drain patterns 150 and 250 may be connected to the first and second channel patterns CP1 and CP2. According to some example embodiments, the first and second source/drain patterns 150 and 250 may be connected to the first and second contact plugs CA1 and CA2 to be described later, respectively.

According to some example embodiments, a distance between the first source/drain patterns 150 facing each other in the first direction DR1 may be smaller than a distance between the second source/drain patterns 250 facing each other in the first direction DR1. Here, the distance between the first source/drain patterns 150 may correspond to the first length d1 along the first direction DR1 of the first sub-gate structure S_GS1 described above, and the distance between the second source/drain patterns 250 may correspond to the second length d2 along the first direction DR1 of the second sub-gate structure S_GS2 described above.

Side surfaces of the first and second source/drain patterns 150 and 250 may have an uneven embossed shape. In other words, the side surfaces of the first and second source/drain patterns 150 and 250 may have a wavy profile. For example, the side surfaces of the first and second source/drain patterns 150 and 250 adjacent to the first and second sub-gate structures S_GS1 and S_GS2, respectively, may have a shape generally convex toward the first and second sub-gate structures S_GS1 and S_GS2, and the side surfaces of the first and second source/drain patterns 150 and 250 adjacent to the first and second channel patterns CP1 and CP2 may have a shape generally concave toward the first and second channel patterns CP1 and CP2.

According to some example embodiments, a lower surface of the first and second source/drain patterns 150 and 250 may be located at a lower level than lower surfaces of the pluralities of first and second sub-gate structures S_GS1 and S_GS2. For example, as shown in FIG. 2 to FIG. 5, the lower surface of the first and second source/drain patterns 150 and 250 may be located closer to a bottom surface of the first and second bottom patterns BP1 and BP2 than a lower surface of the first and second sub-gate structures S_GS1 and S_GS2 located in a lowermost portion.

According to some example embodiments, the first and second source/drain patterns 150 and 250 may be located within first and second recesses 150R and 250R extending along the third direction DR3, respectively. The first and second source/drain patterns 150 and 250 may fill the first and second recesses 150R and 250R. A lower surface of the first and second recesses 150R and 250R may be defined by the first and second bottom patterns BP1 and BP2. A side surface of the first and second recesses 150R and 250R may be defined by the first and second bottom patterns BP1 and BP2, the first and second channel patterns CP1 and CP2, and the first and second sub-gate structures S_GS1 and S_GS2.

According to some example embodiments, the first and second source/drain patterns 150 and 250 may be epitaxial patterns formed by a selective epitaxial growth process utilizing the first and second active patterns AP1 and AP2 as seeds, respectively. According to some example embodiments, the first and second source/drain patterns 150 and 250 may include at least one of silicon (Si) and silicon germanium (SiGe). However, example embodiments are not limited thereto. The first and second channel patterns CP1 and CP2 may be a portion of the first and second active patterns AP1 and AP2 extending between the first and second source/drain patterns 150 and 250. The first and second source/drain patterns 150 and 250 may serve as source/drains of the transistor that uses the first and second channel patterns CP1 and CP2 as channel regions.

The first source/drain pattern 150 may include a first source/drain layer 150a, a second source/drain layer 150b, a third source/drain layer 150c and a fourth source/drain layer 150d. For example, the first source/drain layer 150a, the second source/drain layer 150b, the third source/drain layer 150c and the fourth source/drain layer 150d may sequentially grow from a lower surface and a side surface of a first recess 150R in upward and central directions. The first source/drain layer 150a, the second source/drain layer 150b, the third source/drain layer 150c and the fourth source/drain layer 150d may fill the first recess 150R.

According to some example embodiments, the first source/drain layer 150a may cover an inner sidewall of the first recess 150R. For example, the first source/drain layer 150a may have a U-shaped form along the profile of the first recess 150R.

The second to fourth source/drain layers 150b, 150c, and 150d may fill a remaining region of the first recess 150R excluding the first source/drain layer 150a. Volumes of the second to fourth source/drain layers 150b, 150c, and 150d may be greater than a volume of the first source/drain layer 150a. In other words, a volumetric ratio of the second to fourth source/drain layers 150b, 150c, and 150d with respect to an entire volume of the first source/drain pattern 150 may be greater than a volumetric ratio of the first source/drain layer 150a with respect to the entire volume of the first source/drain pattern 150.

Specifically, for example, the second source/drain layer 150b may be located on the first source/drain layer 150a.

Specifically, for example, a bottom level of the third source/drain layer 150c may be lower than a bottom level of the first contact plug CA1 to be described later. In addition, the third source/drain layer 150c may be located to surround a first silicide pattern SC1.

Specifically, for example, the fourth source/drain layer 150d may fill the region of the first recess 150R remaining after filling the first source/drain layer 150a, the second source/drain layer 150b and the third source/drain layer 150c. That is, the fourth source/drain layer 150d may be disposed to fill the first recess 150R in an upper portion of the third source/drain layer 150c. In other words, the fourth source/drain layer 150d may fill a space of the first recess 150R that is not filled by the first source/drain layer 150a, the second source/drain layer 150b and the third source/drain layer 150c.

According to some example embodiments, the first source/drain layer 150a may have a form surrounding side surfaces and a lower surface of the second source/drain layer 150b.

Meanwhile, as shown in FIG. 2 to FIG. 5, at least a portion of the third source/drain layer 150c may directly contact the first source/drain layer 150a. Since the second source/drain layer 150b is located between a lower surface of the third source/drain layer 150c and the first source/drain layer 150a, the third source/drain layer 150c may not directly contact the first source/drain layer 150a. A side surface of the third source/drain layer 150c may directly contact the first source/drain layer 150a. However, example embodiments are not limited thereto, and as the second source/drain layer 150b is also located between the side surface of the third source/drain layer 150c and the first source/drain layer 150a, the side surface of the third source/drain layer 150c may not directly contact the first source/drain layer 150a.

According to some example embodiments, the channel patterns CP1 may be in contact with the first source/drain layer 150a, and may not be in contact with the second to fourth source/drain layers 150b, 150c, and 150ds. Therefore, the first source/drain layer 150a may be located between the channel patterns CP1 and the second to fourth source/drain layers 150b, 150c, and 150ds.

However, example embodiments are not limited thereto, and at least a portion of the channel patterns CP1 may be in contact with the second to fourth source/drain layers 150b, 150c, and 150ds.

According to some example embodiments, the first source/drain pattern 150 may include silicon-germanium (SiGe). However, example embodiments are not limited thereto.

Each of the first to fourth source/drain layers 150a, 150b, 150c, and 150d may contain germanium (Ge) of different concentrations.

According to some example embodiments, a concentration of germanium (Ge) included in at least one among the second source/drain layer 150b or the third source/drain layer 150c may be greater than a concentration of germanium (Ge) included in the first source/drain layer 150a.

For example, the first source/drain layer 150a may contain germanium (Ge) of a relatively low concentration. In some example embodiments, the first source/drain layer 150a may include only silicon (Si) excluding germanium (Ge).

In addition, for example, the second source/drain layer 150b may contain germanium (Ge) of a relatively high concentration.

A concentration of germanium (Ge) of the second source/drain layer 150b may increase in the third direction DR3.

According to some example embodiments, the second source/drain layer 150b may not include conductive impurities.

In addition, for example, the third source/drain layer 150c may contain germanium (Ge) of a relatively high concentration.

A concentration of germanium (Ge) of the third source/drain layer 150c may increase in the third direction DR3.

According to some example embodiments, the third source/drain layer 150c may include first conductivity type impurities. For example, the third source/drain layer 150c may include an impurity (e.g., boron) that causes the first source/drain pattern 150 to have a P-type.

According to some example embodiments, the second source/drain layer 150b and the third source/drain layer 150c may be distinguished according to whether the first source/drain pattern 150 includes the first conductivity type impurities. For example, a layer that does not include the first conductivity type impurities may be distinguished as the second source/drain layer 150b, and a layer that includes the first conductivity type impurities may be distinguished as the third source/drain layer 150c.

For example, the fourth source/drain layer 150d may contain germanium (Ge) of a relatively low concentration. In some example embodiments, the fourth source/drain layer 150d may include only silicon (Si) excluding germanium (Ge).

According to some example embodiments, the second source/drain pattern 250 may include a fifth source/drain layer 250a, a sixth source/drain layer 250b, a seventh source/drain layer 250c and an eighth source/drain layer 250d. For example, the fifth source/drain layer 250a, the sixth source/drain layer 250b, the seventh source/drain layer 250c and the eighth source/drain layer 250d may sequentially grow from a lower surface and a side surface of a second recess 250R in upward and central directions. The fifth source/drain layer 250a, the sixth source/drain layer 250b, the seventh source/drain layer 250c and the eighth source/drain layer 250d may fill the second recess 250R.

According to some example embodiments, the fifth source/drain layer 250a may cover an inner sidewall of the second recess 250R. For example, the fifth source/drain layer 250a may have a U-shaped form along the profile of the second recess 250R.

According to some example embodiments, the sixth to eighth source/drain layers 250b, 250c, and 250d may fill a remaining region of the second recess 250R excluding the fifth source/drain layer 250a. Volumes of the sixth to eighth source/drain layers 250b, 250c, and 250d may be greater than a volume of the fifth source/drain layer 250a. In other words, a volumetric ratio of the sixth to eighth source/drain layers 250b, 250c, and 250d with respect to an entire volume of the second source/drain pattern 250 may be greater than a volumetric ratio of the fifth source/drain layer 250a with respect to an entire volume of the second source/drain pattern 250.

Specifically, for example, the sixth source/drain layer 250b may be located on the fifth source/drain layer 250a. A thickness of the sixth source/drain layer 250b along the third direction DR3 may be variously changed.

Specifically, for example, a bottom level of the seventh source/drain layer 250c may be lower than a bottom level of the second contact plug CA2 to be described later. In addition, the seventh source/drain layer 250c may be located to surround a second silicide pattern SC2. A thickness of the seventh source/drain layer 250c along the third direction DR3 may be variously changed. For example, the thickness of the seventh source/drain layer 250c along the third direction DR3 may be variously changed according to a position of the second contact plug CA2 to be described later. More specifically, for example, the thickness of the seventh source/drain layer 250c may be variously changed such that a distance from an upper surface of the substrate 100 to the second contact plug CA2 may be proportional to a distance from the upper surface of the substrate 100 to the seventh source/drain layer 250c.

Specifically, for example, the eighth source/drain layer 250d may fill the region of the second recess 250R remaining after filling the fifth source/drain layer 250a, the sixth source/drain layer 250b and the seventh source/drain layer 250c. That is, the eighth source/drain layer 250d may be disposed to fill the second recess 250R in an upper portion of the seventh source/drain layer 250c. In other words, the eighth source/drain layer 250d may fill a space of the second recess 250R that is not filled by the fifth source/drain layer 250a, the sixth source/drain layer 250b and the seventh source/drain layer 250c.

According to some example embodiments, the fifth source/drain layer 250a may have a form surrounding side surfaces and a lower surface of the sixth source/drain layer 250b.

According to some example embodiments, shown in FIG. 2, as FIG. 4 and FIG. 5, the seventh source/drain layer 250c may directly contact the fifth source/drain layer 250a.

According to another embodiment, as shown in FIG. 3, as the sixth source/drain layer 250b is located between the seventh source/drain layer 250c and the fifth source/drain layer 250a, the seventh source/drain layer 250c may not directly contact the fifth source/drain layer 250a.

The channel patterns CP2 may be in contact with the fifth source/drain layer 250a, and may not be in contact with the sixth to eighth source/drain layers 250b, 250c, and 250d. Therefore, the fifth source/drain layer 250a may be located between the channel patterns CP2 and the sixth to eighth source/drain layers 250b, 250c, and 250d.

However, example embodiments are not limited thereto, and at least a portion of the channel patterns CP2 may be in contact with the sixth to eighth source/drain layers 250b, 250c, and 250d.

According to some example embodiments, the second source/drain pattern 250 may include silicon-germanium (SiGe). However, example embodiments are not limited thereto.

According to some example embodiments, each of the fifth to eighth source/drain layers 250a, 250b, 250c, and 250d may contain germanium (Ge) of different concentrations.

According to some example embodiments, a concentration of germanium (Ge) included in at least one among the sixth source/drain layer 250b or the seventh source/drain layer 250c may be greater than a concentration of germanium (Ge) included in the fifth source/drain layer 250a.

For example, the fifth source/drain layer 250a may contain germanium (Ge) of a relatively low concentration. In some example embodiments, the fifth source/drain layer 250a may include only silicon (Si) excluding germanium (Ge).

In addition, for example, the sixth source/drain layer 250b may contain germanium (Ge) of a relatively high concentration. A concentration of germanium (Ge) of the sixth source/drain layer 250b may increase in the third direction DR3.

According to some example embodiments, the sixth source/drain layer 250b may not include the first conductivity type impurities.

In addition, for example, the seventh source/drain layer 250c may contain germanium (Ge) of a relatively high concentration. A concentration of germanium (Ge) of the seventh source/drain layer 250c may increase in the third direction DR3.

According to some example embodiments, the seventh source/drain layer 250c may include the first conductivity type impurities. For example, the seventh source/drain layer 250c may include an impurity (e.g., boron) that causes the second source/drain pattern 250 to have a P-type.

According to some example embodiments, the sixth source/drain layer 250b and the seventh source/drain layer 250c may be distinguished according to whether it includes the first conductivity type impurities. For example, a layer that does not include the first conductivity type impurities may be distinguished as the sixth source/drain layer 250b, and a layer that includes the first conductivity type impurities may be distinguished as the seventh source/drain layer 250c.

For example, the eighth source/drain layer 250d may contain germanium (Ge) of a relatively low concentration. In some example embodiments, the eighth source/drain layer 250d may include only silicon (Si) excluding germanium (Ge).

Referring to FIG. 2 to FIG. 4, depending on some example embodiments, a height in the third direction DR3 of an upper surface of a central portion (central in the first direction DR1) of the first source/drain pattern 150 may be higher than or the same as a height in the third direction DR3 of an upper surface of edge (the edge in the first direction DR1).

According to some example embodiments, a cross-section of the first source/drain pattern 150 along the first direction DR1 and the third direction DR3 may have a generally flat upper surface. In other words, a height in the third direction DR3 of the upper surface of the first source/drain pattern 150 along the first direction DR1 may be constant. Accordingly, the upper surface of the central portion of the first source/drain pattern 150 along the first direction DR1 may have the same height as the upper surface of the edge.

According to some example embodiments, a height in the third direction DR3 of an upper surface of a central portion (central in the first direction DR1) of the second source/drain pattern 250 may be lower than the height in the third direction DR3 of the upper surface of the edge (the edge in the first direction DR1).

According to some example embodiments, a cross-section of the second source/drain pattern 250 along the first direction DR1 and the third direction DR3 may have a concave upper surface. In other words, an upper surface of a central portion of the eighth source/drain layer 250d in the first direction DR1 may be lower than the upper surface of the edge.

For example, as shown in FIG. 2 and FIG. 3, on an upper surface of the eighth source/drain layer 250d, a slope with respect to the upper surface of the substrate 100 may gradually increase and then gradually decrease from a central portion to an edge along the first direction DR1.

Alternatively, for example, as shown in FIG. 4, on the upper surface of the eighth source/drain layer 250d, the slope with respect to the upper surface of the substrate 100 may gradually increase from a central portion to an edge along the first direction DR1.

In some example embodiments, an upper surface of the central portion of the eighth source/drain layer 250d may be lower than an upper surface of the fourth source/drain layer 150d.

Referring to FIG. 5, depending on another embodiment, heights in the third direction DR3 of upper surfaces of central portions (central in the first direction DR1) of the first and second source/drain patterns 150 and 250 may be higher than, or the same as, the height in the third direction DR3 of the upper surface of the edge (the edge in the first direction DR1).

According to some example embodiments, the cross-sections of the first and second source/drain patterns 150 and 250 along the first direction DR1 and the third direction DR3 may have a generally flat upper surface. In other words, heights in the third direction DR3 of upper surfaces of the first and second source/drain patterns 150 and 250 along the first direction DR1 may be constant. Accordingly, upper surfaces of central portions of the first and second source/drain patterns 150 and 250 along the first direction DR1 may have the same height in the third direction DR3 as the upper surface of the edge.

In some example embodiments, a height of the upper surface of the central portion of the eighth source/drain layer 250d may be similar to or the same as the height of the upper surface of the fourth source/drain layer 150d.

According to some example embodiments, it is described that the first and second source/drain patterns 150 and 250 are formed in multiple layers, but example embodiments are not limited thereto, and the first and second source/drain patterns 150 and 250 may be formed of a single layer or bilayer including a semiconductor material.

According to some example embodiments, the first and second contact plugs CA1 and CA2 may be located on the first and second source/drain patterns 150 and 250, respectively. For example, the first and second contact plugs CA1 and CA2 may be electrically connected to the first and second source/drain patterns 150 and 250, respectively.

In more detail, the first and second contact plugs CA1 and CA2 may overlap with the first and second source/drain patterns 150 and 250 in the third direction DR3. Specifically, the first and second contact plugs CA1 and CA2 may overlap with the first and second source/drain patterns 150 and 250 in the third direction DR3 interposing the first and second silicide patterns SC1 and SC2, respectively.

According to some example embodiments, a pair of first contact plugs CA1 may be disposed interposing a first main gate electrode 120M. In other words, the first contact plug CA1 may be located adjacent to the first main gate electrode 120M in the first direction DR1. In the same way, a pair of second contact plugs CA2 may be disposed interposing a second main gate electrode 220M. In other words, the second contact plug CA2 may be located adjacent to the second main gate electrode 220M in the first direction DR1.

According to some example embodiments, the first contact plug CA1 may be located between the first gate spacers 140 located apart in the first direction DR1. The second contact plug CA2 may be located between the second gate spacers 240 located apart in the first direction DR1.

FIG. 2 to FIG. 5 illustrate that a side surface of the first and second contact plugs CA1 and CA2 is not in contact with the first and second gate spacers 140 and 240, but example embodiments are not limited thereto, and the side surface of the first and second contact plugs CA1 and CA2 may directly contact the first and second gate spacers 140 and 240.

According to some example embodiments, the first and second silicide patterns SC1 and SC2 may be interposed between the first and second contact plugs CA1 and CA2 and the first and second source/drain patterns 150 and 250, respectively. The first and second contact plugs CA1 and CA2 may be electrically connected to the first and second source/drain patterns 150 and 250 through the first and second silicide patterns SC1 and SC2, respectively.

According to some example embodiments, the first and second silicide patterns SC1 and SC2 may include metal-silicide, and may include, as an example, titanium-silicide, tantalum-silicide, tungsten-silicide, nickel-silicide, cobalt-silicide, or a combination thereof. However, example embodiments are not limited thereto.

According to some example embodiments, the first and second contact plugs CA1 and CA2 may include first and second conductive patterns FM1 and FM2 and first and second barrier patterns BM1 and BM2 surrounding the first and second conductive patterns FM1 and FM2, respectively.

For example, the first and second conductive patterns FM1 and FM2 may include aluminum, copper, tungsten, molybdenum, or a combination thereof. However, example embodiments are not limited thereto.

According to some example embodiments, the first and second barrier patterns BM1 and BM2 may cover side walls and a bottom surface of the first and second conductive patterns FM1 and FM2. According to some example embodiments, it is illustrated that the first and second barrier patterns BM1 and BM2 are formed in single layers, but example embodiments are not limited thereto, the first and second barrier patterns BM1 and BM2 may be formed of multiple layers including at least one among a conductive metal or a conductive metal nitride.

According to some example embodiments, the first and second barrier patterns BM1 and BM2 may include a metal layer or a metal nitride layer. The metal layer may include titanium, tantalum, tungsten, nickel, cobalt, platinum, or a combination thereof. The metal nitride layer may include a titanium nitride layer (TiN), a tantalum nitride layer (TaN), a tungsten nitride layer (WN), a nickel nitride layer (NiN), a cobalt nitride layer (CoN), a platinum nitride layer (PtN), or a combination thereof. However, example embodiments are not limited thereto.

According to some example embodiments, for example, a lower surface of the first and second contact plugs CA1 and CA2 may be lower than a lower surface of the channel pattern located in an uppermost portion among the pluralities of the first and second channel patterns CP1 and CP2. The lower surface of the first and second contact plugs CA1 and CA2 may be located between the lower surface of the channel pattern located in a lowermost portion among the pluralities of the first and second channel patterns CP1 and CP2 and the lower surface of the channel pattern located in an uppermost portion. However, it is not limited thereto, and the lower surface of the first and second contact plugs CA1 and CA2 may be lower than the lower surface of the channel pattern located in a lowermost portion among the pluralities of the first and second channel patterns CP1 and CP2.

Referring to FIG. 2 to FIG. 4, according to some example embodiments, the bottom surface level of the first contact plug CA1 and the bottom surface level of the second contact plug CA2 may be different from each other. For example, the bottom surface level of the first contact plug CA1 may be higher than the bottom surface level of the second contact plug CA2.

In other words, a first distance L11 between an uppermost surface of the first source/drain pattern 150 and a bottom surface of the first contact plug CA1 may be smaller than a second distance L21 between an uppermost surface of the second source/drain pattern 250 and a bottom surface of the second contact plug CA2.

Accordingly, a bottom surface level of the first silicide pattern SC1 and a bottom surface level of the second silicide pattern SC2 may be different from each other.

According to some example embodiments, the bottom surface level of the first silicide pattern SC1 may be higher than the bottom surface level of the second silicide pattern SC2. Accordingly, a bottom surface of the first silicide pattern SC1 may be located farther from the upper surface of the substrate 100 than a bottom surface of the second silicide pattern SC2.

Referring to FIG. 5, according to some example embodiments, the bottom surface level of the first contact plug CA1 may be similar to or the same as the bottom surface level of the second contact plug CA2.

In other words, a third distance L13 between the uppermost surface of the first source/drain pattern 150 and the bottom surface of the first contact plug CA1 may be similar to or the same as a fourth distance L23 between the uppermost surface of the second source/drain pattern 250 and the bottom surface of the second contact plug CA2.

Accordingly, the bottom surface level of the first silicide pattern SC1 and the bottom surface level of the second silicide pattern SC2 may be similar to or the same as each other.

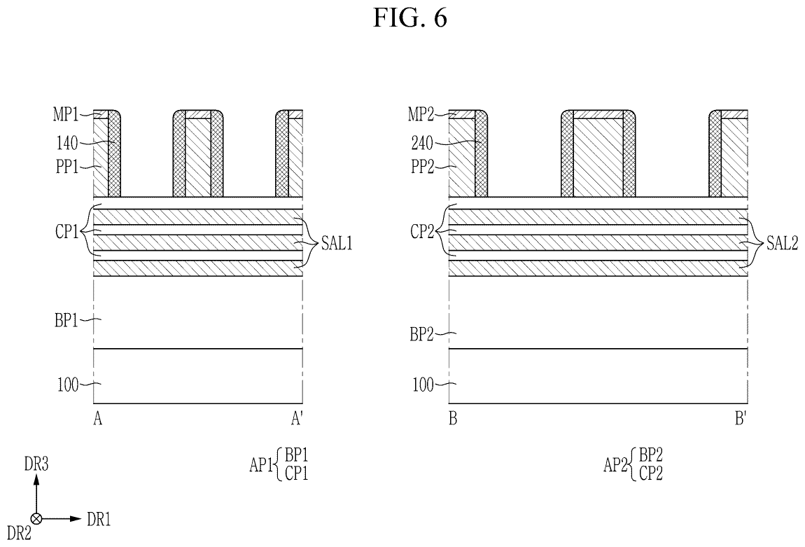

FIG. 6 to FIG. 18 are cross-sectional views for explaining a manufacturing method of a semiconductor device according to some example embodiments. FIG. 6 to FIG. 18 is a cross-sectional view taken along lines A-A′ and B-B′ of FIG. 1.

Referring to FIG. 6, the first active pattern AP1 and the second active pattern AP2 may be formed on the first region R1 of the substrate 100 (e.g., the first region R1 of FIG. 1) and the second region R2 (e.g., the second region R2 of FIG. 1), respectively.

First, the first and second sacrificial layers SAL1 and SAL2 and the first and second channel patterns CP1 and CP2 alternately stacked on the substrate 100 may be formed. The first and second sacrificial layers SAL1 and SAL2 may include silicon (Si), germanium (Ge), or silicon-germanium (SiGe), and the first and second channel patterns CP1 and CP2 may include silicon (Si), germanium (Ge), silicon-germanium (SiGe). For example, the first and second sacrificial layers SAL1 and SAL2 may include silicon-germanium (SiGe), and the first and second channel patterns CP1 and CP2 may include silicon (Si). However, example embodiments are not limited thereto. Each of the first active pattern AP1 and the second active pattern AP2 may include the first and second sacrificial layers SAL1 and SAL2 and the first and second channel patterns CP1 and CP2 alternately stacked on their upper portions.

Although not shown in the drawings, mask patterns may be formed on the first region R1 and the second region R2 of the substrate 100, respectively. The mask pattern may have a line shape or bar shape extending in the first direction DR1. By performing a patterning process by using the mask patterns as an etching mask, a trench defining the first active pattern AP1 and the second active pattern AP2 may be formed. Accordingly, in the logic cell region, the first active pattern AP1 and the second active pattern AP2 may be formed in the first region R1 and the second region R2, respectively. Subsequently, a device isolation layer to fill the trench may be formed on the substrate 100. For example, the device isolation layer may be formed to cover both of the first active pattern AP1 and the second active pattern AP2. For example, the device isolation layer may include an insulating material such as silicon oxide. Subsequently, the first and second sacrificial layers SAL1 and SAL2 above the first active pattern AP1 and the second active pattern AP2 may be exposed. For example, the mask patterns may be formed on the first active pattern AP1 and the second active pattern AP2 of the logic cell region, and by performing a patterning process by using the mask patterns as an etching mask, the device isolation layer may be recessed until the first and second sacrificial layers SAL1 and SAL2 are exposed. By this, the upper portion of each of the first active pattern AP1 and the second active pattern AP2 may be exposed above the device isolation layer. In other words, the upper portion of each of the first active pattern AP1 and the second active pattern AP2 may protrude in the third direction DR3 of the device isolation layer.

Subsequently, front surfaces of the sacrificial layer may be formed on the first region R1 and the second region R2 of the substrate 100, first and second hard mask patterns MP1 and MP2 may be formed on the sacrificial layer of each of the first region R1 and the second region R2, and by patterning the sacrificial layer by using the first and second hard mask patterns MP1 and MP2 as etching masks, first and second sacrificial pattern PP1 and PP2 may be formed.

For example, the first and second sacrificial pattern PP1 and PP2 may be formed in a line shape or a bar shape extending in the second direction DR2. The first and second sacrificial pattern PP1 and PP2 may be arranged along the first direction DR1 with a desired (and/or alternatively predetermined) pitch. The sacrificial layer may include polysilicon.

Subsequently, the pair of first gate spacers 140 may be formed on both sidewalls of each of first sacrificial patterns PP1. In addition, the pair of second gate spacers 240 may be formed on both sidewalls of each of second sacrificial patterns PP2.

For example, a gate spacer layer may be conformally formed on the front surfaces of the first region R1 and the second region R2 of the substrate 100, and the first and second gate spacers 140 and 240 may be formed by anisotropically etching the gate spacer layer.

For example, the gate spacer layer may include SiCN, SiCON, SiN, or a combination thereof. In addition, the gate spacer layer may be formed of multiple layers including SiCN, SiCON, SiN, or a combination thereof. However, example embodiments are not limited thereto.

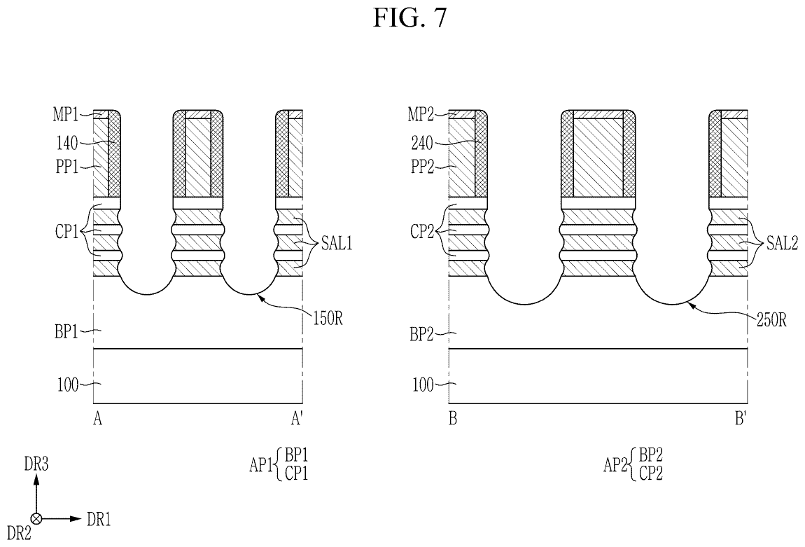

Referring to FIG. 7, the first recess 150R and the second recess 250R may be formed by patterning the first active pattern AP1 and the second active pattern AP2.

According to some example embodiments, the first recess 150R may be formed by patterning the first active pattern AP1, and the second recess 250R may be formed by patterning the second active pattern AP2.

According to some example embodiments, by etching an upper portion of the first active pattern AP1 by using the first hard mask pattern MP1 and the first gate spacer 140 as etching masks, the first recess 150R may be formed. The first recess 150R may be formed between a pair of first sacrificial patterns PP1.

In the same way, according to some example embodiments, by etching an upper portion of the second active pattern AP2 by using the second hard mask pattern MP2 and the second gate spacer 240 as etching masks, the second recess 250R may be formed. The second recess 250R may be formed between a pair of second sacrificial patterns PP2.

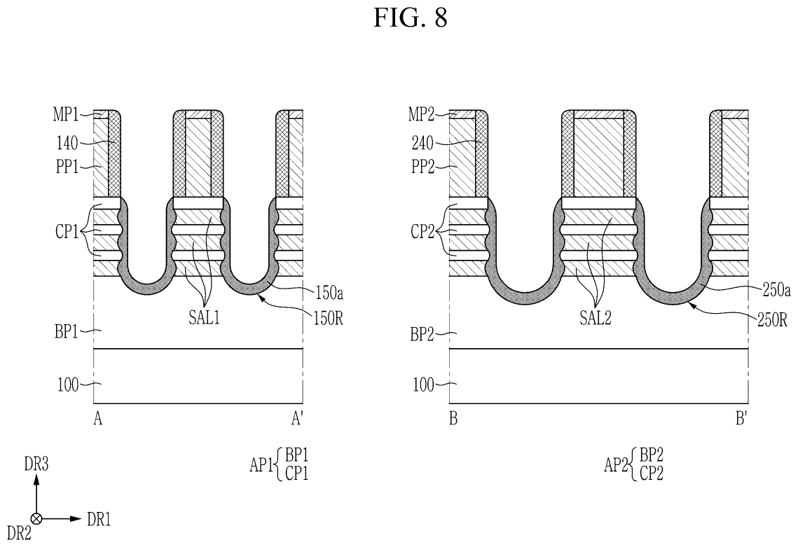

Referring to FIG. 8 to FIG. 11, the first source/drain pattern 150 may be formed within the first recess 150R, and the second source/drain pattern 250 may be formed within the second recesses 250R.

Referring to FIG. 8, by performing a first selective epitaxial growth (SEG) process by using the inner sidewall of the first recess 150R as a seed layer, the first source/drain layer 150a may be formed. The first source/drain layer 150a may be grown by using the first channel patterns CP1 and the first bottom pattern BP1 exposed by the first recess 150R as seeds. For example, the first SEG process may include a chemical vapor deposition (CVD) process or molecular-beam epitaxy (MBE) process. However, example embodiments are not limited thereto.

The first source/drain layer 150a may include a semiconductor element (e.g., SiGe) having a lattice constant that is greater than a lattice constant of the semiconductor element of the first active pattern AP1. The first source/drain layer 150a may contain germanium (Ge) of a relatively low concentration. As another example, the first source/drain layer 150a may contain only silicon (Si) excluding germanium (Ge).

Similarly, by performing the first selective epitaxial growth (SEG) process by using the inner sidewall of the second recess 250R as a seed layer, the fifth source/drain layer 250a may be formed. The fifth source/drain layer 250a may be grown by using the second channel patterns CP2 and the second bottom pattern BP2 exposed by the second recess 250R as seeds. For example, the first SEG process may include a chemical vapor deposition (CVD) process or molecular-beam epitaxy (MBE) process. However, example embodiments are not limited thereto.

The fifth source/drain layer 250a may include a semiconductor element (e.g., SiGe) having a lattice constant that is greater than a lattice constant of the semiconductor element of the second active pattern AP2. The fifth source/drain layer 250a may contain germanium (Ge) of a relatively low concentration. As another example, the fifth source/drain layer 250a may contain only silicon (Si) excluding germanium (Ge).

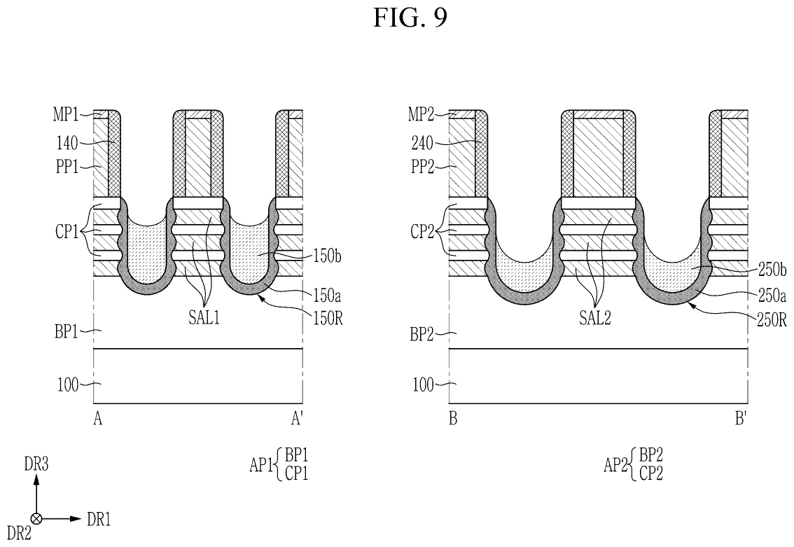

Referring to FIG. 9, by performing a second SEG process on the first source/drain layer 150a, the second source/drain layer 150b may be formed. The second source/drain layer 150b may contain germanium (Ge) of a relatively high concentration.

Similarly, by performing the second SEG process on the fifth source/drain layer 250a, the sixth source/drain layer 250b may be formed. While performing the second SEG process, the thickness of the sixth source/drain layer 250b may be adjusted by adjusting time and/or pressure. For example, depending on the condition of the second SEG process, the thickness of the sixth source/drain layer 250b in the third direction DR3 may be variously changed.

The sixth source/drain layer 250b may contain germanium (Ge) of a relatively high concentration.

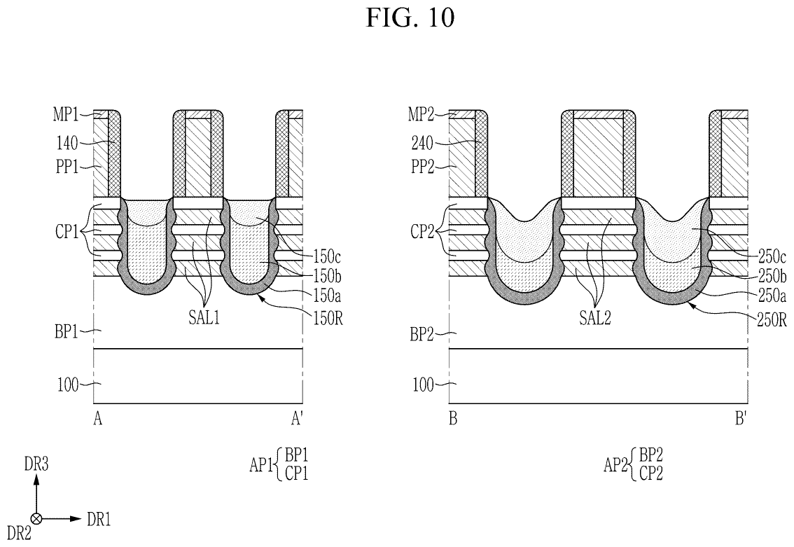

Referring to FIG. 10, by performing a third SEG process on the second source/drain layer 150b, the third source/drain layer 150c may be formed. The third source/drain layer 150c may contain germanium (Ge) of a relatively high concentration.

Similarly, by performing the second SEG process on the sixth source/drain layer 250b, the seventh source/drain layer 250c may be formed. While performing the third SEG process, the thickness of the seventh source/drain layer 250c may be adjusted by adjusting time and/or pressure. For example, depending on the condition of the third SEG process, the thickness of the seventh source/drain layer 250c in the third direction DR3 may be variously changed. Accordingly, as described above, the bottom level of the seventh source/drain layer 250c may be lower than the bottom level of the second contact plug CA2. In addition, the seventh source/drain layer 250c may be located to surround the second silicide pattern SC2.

The seventh source/drain layer 250c may contain germanium (Ge) of a relatively high concentration.

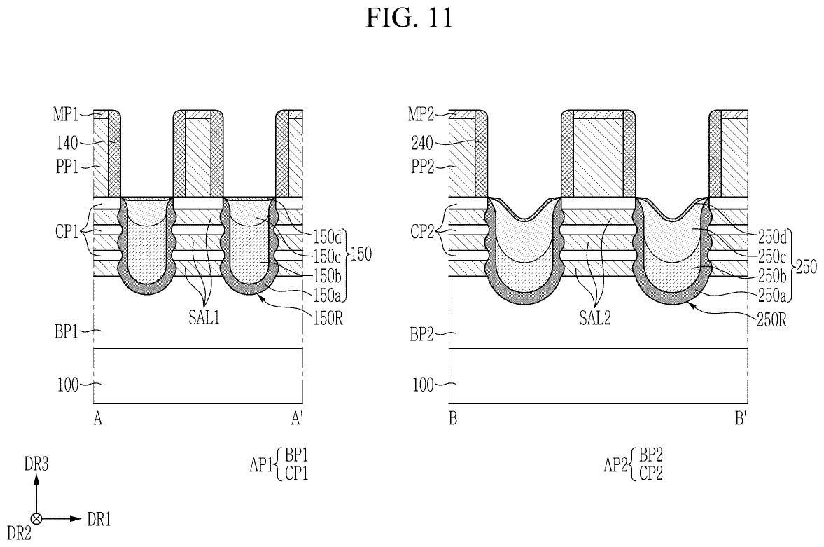

Referring to FIG. 11, the fourth source/drain layer 150d may be formed to completely fill the first recess 150R. The first to fourth source/drain layers 150a, 150b, 150c, and 150d may configure the first source/drain pattern 150.

According to some example embodiments, the fourth source/drain layer 150d may have a generally flat upper surface. In other words, a height in the third direction DR3 of the upper surface of the fourth source/drain layer 150d along the first direction DR1 may be constant. Accordingly, an upper surface of a central portion of the fourth source/drain layer 150d along the first direction DR1 may have the same height in the third direction DR3 as the upper surface of the edge.

According to some example embodiments, the eighth source/drain layer 250d may be formed to completely fill the second recess 250R. The fifth to eighth source/drain layers 250a, 250b, 250c, and 250d may configure the second source/drain pattern 250.

According to some example embodiments, the height in the third direction DR3 of the upper surface of the central portion (central in the first direction DR1) of the eighth source/drain layer 250d may be lower than the height in the third direction DR3 of the upper surface of the edge (the edge in the first direction DR1).

According to some example embodiments, the eighth source/drain layer 250d may have a concave upper surface. In other words, the upper surface of the central portion of the eighth source/drain layer 250d in the first direction DR1 may be lower than the upper surface of the edge.

For example, on the upper surface of the eighth source/drain layer 250d, the slope with respect to the upper surface of the substrate 100 may gradually increase and then gradually decrease from a central portion to an edge along the first direction DR1.

Alternatively, for example, on the upper surface of the eighth source/drain layer 250d, the slope with respect to the upper surface of the substrate 100 may gradually increase from a central portion to an edge along the first direction DR1.

According to some example embodiments, after the first and second source/drain patterns 150 and 250 are formed, impurities may be implanted into the first and second source/drain patterns 150 and 250. First and second source/drain pattern 150 may be doped to have a first conductivity type (e.g., P-type).

Accordingly, the third source/drain layer 150c and the seventh source/drain layer 250c may include an impurity (e.g., boron) that causes the first and second source/drain patterns 150 and 250 to have a P-type, respectively. Meanwhile, the second source/drain layer 150b and the sixth source/drain layer 250b may not include conductive impurities.

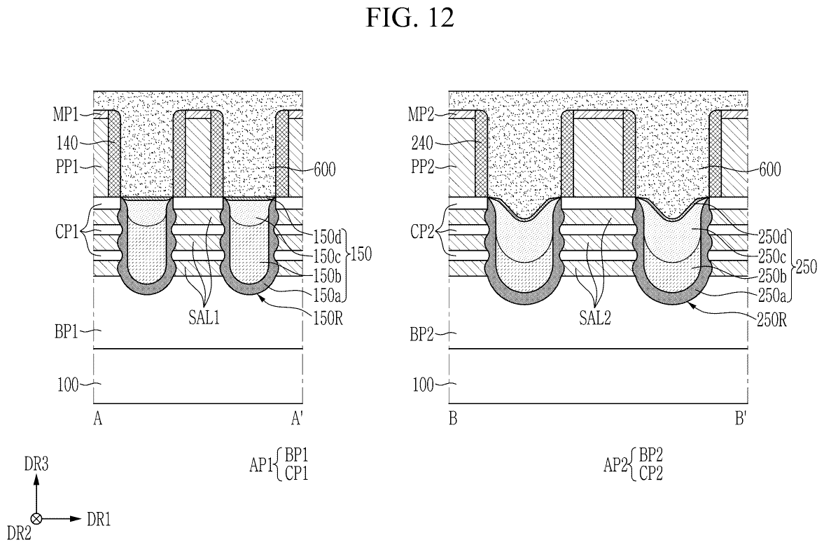

Referring to FIG. 12 to FIG. 14, the first and second interlayer insulating layers 160 and 260 may be formed, and the first and second sacrificial layers SAL1 and SAL2 may be removed.

Referring to FIG. 12, a preliminary interlayer insulating layer 600 is formed to cover the first and second source/drain patterns 150 and 250, the first and second hard mask patterns MP1 and MP2, and the first and second gate spacers 140 and 240. For example, the preliminary interlayer insulating layer 600 may include silicon oxide.

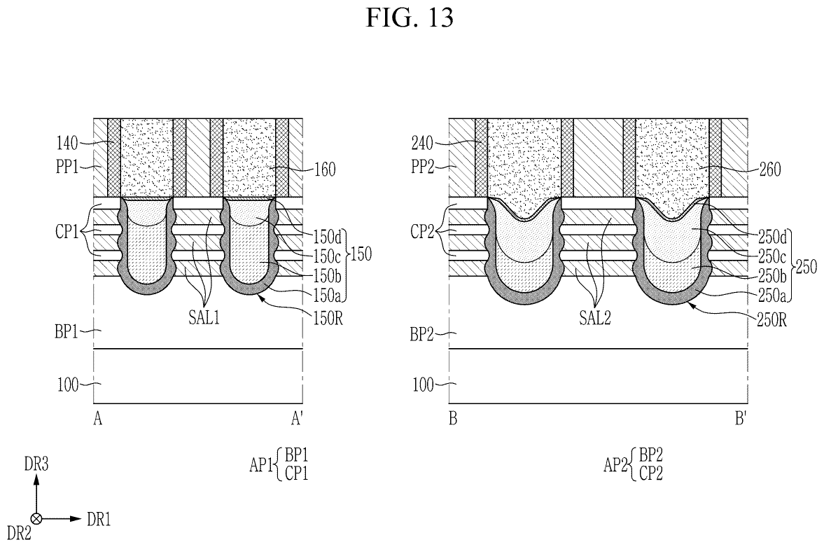

Referring to FIG. 13, by planarizing the preliminary interlayer insulating layer 600 until an upper surface of the first and second sacrificial pattern PP1 and PP2 are exposed, the first and second interlayer insulating layers 160 and 260 located on the first and second source/drain patterns 150 and 250, respectively, may be formed. The planarization of the preliminary interlayer insulating layer 600 may be performed by using a chemical mechanical polishing (CMP) process. During the planarization process, the first and second hard mask patterns MP1 and MP2 may be all removed. As a result, the upper surface of the first and second interlayer insulating layers 160 and 260 may be located at substantially the same level as the upper surface of the first and second sacrificial pattern PP1 and PP2 and an upper surface of the first and second gate spacers 140 and 240.

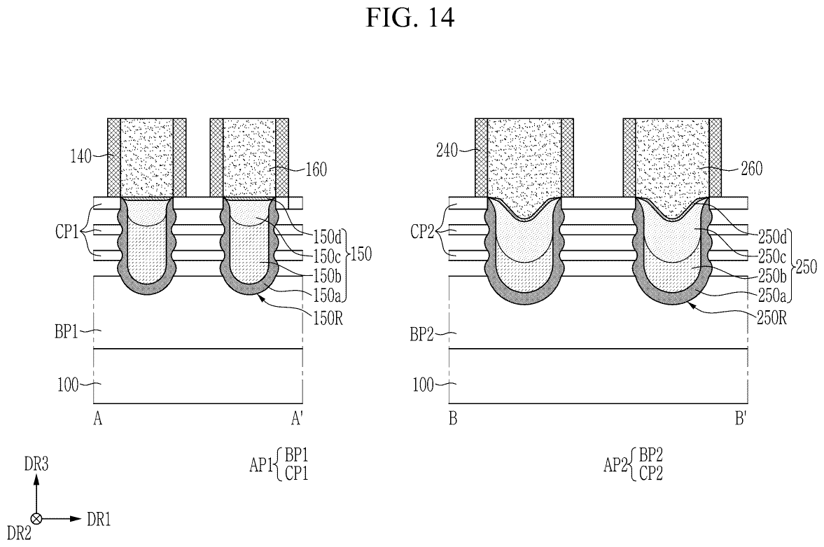

Referring to FIG. 14, the exposed first and second sacrificial pattern PP1 and PP2 may be selectively removed. As the first and second sacrificial pattern PP1 and PP2 are removed, first empty spaces exposing the first and second active patterns AP1 and AP2 may be formed.

As the first and second sacrificial pattern PP1 and PP2 are removed, through the first empty space, the first and second sacrificial layers SAL1 and SAL2 of each of the first and second active patterns AP1 and AP2 may be exposed.

Subsequently, the first and second sacrificial layers SAL1 and SAL2 exposed through the first empty space may be selectively removed.

For example, by performing an etching process for selectively etching the first and second sacrificial layers SAL1 and SAL2, only the first and second sacrificial layers SAL1 and SAL2 may be removed while leaving the first and second channel patterns CP1 and CP2 intact. The etching process may have a high etch rate with respect to silicon-germanium having a relatively high germanium concentration. For example, the etching process may have a high etch rate silicon-germanium having the germanium concentration greater than 10 at %.

During the etching process, the first and second sacrificial layers SAL1 and SAL2 on the first region R1 and the second region R2 may be removed. The etching process may be dry etching. The etching material used in the etching process may rapidly remove the first and second sacrificial layers SAL1 and SAL2 having a relatively high germanium concentration.

As the first and second sacrificial layers SAL1 and SAL2 are selectively removed, only the first and second channel patterns CP1 and CP2 may remain on each of the first and second active patterns AP1 and AP2. Through regions where the first and second sacrificial layers SAL1 and SAL2 are removed, second empty spaces may be formed. The second empty spaces may be located between the first and second channel patterns CP1 and CP2.

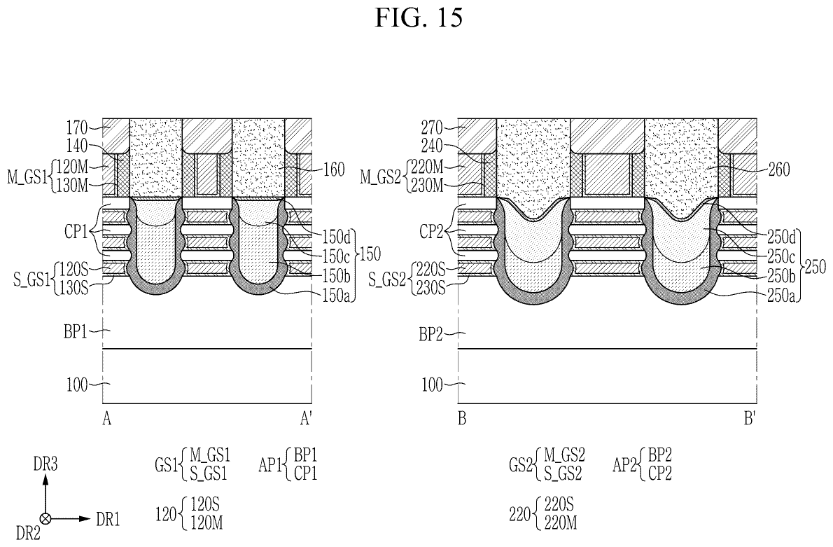

Referring to FIG. 15, the first and second gate structures GS1 and GS2 and the first and second capping layers 170 and 270 may be further formed.

According to some example embodiments, first sub-gate insulation layers 130S and first main gate insulation layer 130M may be conformally formed within the first and second empty spaces. Thereafter, a first gate electrode 120 may be formed on the first sub-gate insulation layers 130S and first main gate insulation layer 130M. The first gate electrode 120 may be formed to fill the first and second empty spaces.

For example, the first gate electrode 120 may include the first sub-gate electrode 120S that fills the second empty spaces. The first gate electrode 120 may further include the first main gate electrode 120M that fills the first empty space.

Similarly, a second sub-gate insulation layers 230S and second main gate insulation layer 230M may be conformally formed within the first and second empty spaces. Thereafter, a second gate electrode 220 may be formed on the second sub-gate insulation layers 230S and second main gate insulation layer 230M. The second gate electrode 220 may be formed to fill the first and second empty spaces.

For example, the second gate electrode 220 may include the second sub-gate electrode 220S that fills the second empty spaces. The second gate electrode 220 may further include the second main gate electrode 220M that fills the first empty space.

Subsequently, first and second capping layers 170 and 270 covering the first and second main gate electrodes 120M and 220M may be formed on the first and second main gate electrodes 120M and 220M, respectively.

According to some example embodiments, the first and second capping layers 170 and 270 may be located on the first and second main gate structures M_GS1 and M_GS2, respectively. The first and second capping layers 170 and 270 may be located on the first and second main gate structures M_GS1 and M_GS2 and the first and second gate spacers 140 and 240.

The first and second capping layers 170 and 270 may include, for example, at least one of silicon nitride (SiN), silicon nitride oxide (SiON), silicon (Si) carbonitride (SiCN), silicon carbonate nitride (SiOCN) and combination thereof. However, example embodiments are not limited thereto.

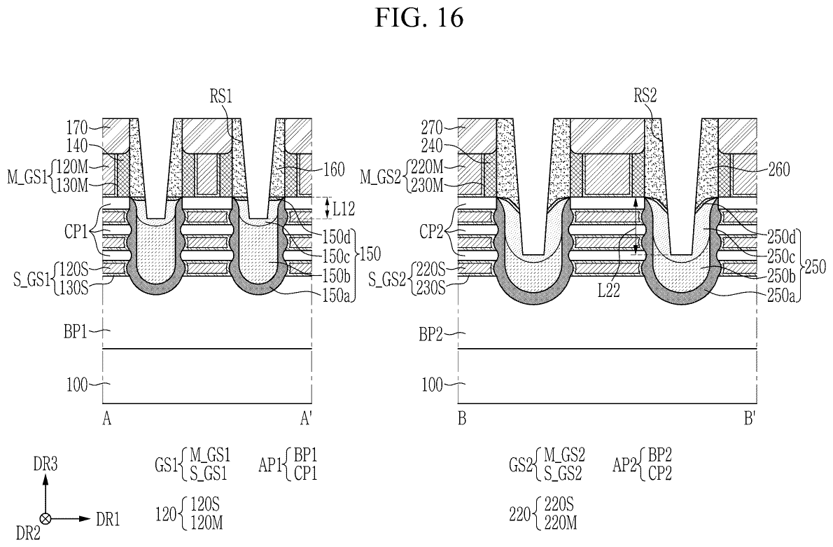

Referring to FIG. 16 to FIG. 18, the first and second contact plugs CA1 and CA2 penetrating the first and second interlayer insulating layers 160 and 260 and being electrically connected to the first and second source/drain patterns 150 and 250 may be formed.

Referring to FIG. 16, after forming the interlayer insulating layer (not shown) on the first gate structure GS1, the first gate spacer 140 and a first interlayer insulating layer 160, a first contact trench RS1 may be formed by performing the etching process. Similarly, after forming the interlayer insulating layer (not shown) on the second gate structure GS2, the second gate spacer 240 and the second interlayer insulating layer 260, a second contact trench RS2 may be formed by performing the etching process.

During the etching process, by removing at least a portion of the first interlayer insulating layer 160 formed between the first gate structures GS1, the first contact trench RS1 exposing at least a portion of the first source/drain pattern 150 may be formed. Similarly, during the etching process, by removing at least a portion of the second interlayer insulating layer 260 formed between the second gate structures GS2, the second contact trench RS2 exposing at least a portion of the second source/drain pattern 250 may be formed.

For example, first and second contact trenches R21 and RS2 may be formed to expose the upper surfaces of the central portions of the first and second source/drain patterns 150 and 250 along the first direction DR1, respectively.

As described above, whereas the first source/drain pattern 150 has a flat upper surface in the cross-section in the first direction DR1, in the second source/drain pattern 250, the cross-section in the first direction DR1 has a concave upper surface in a central portion and the upper surface of the central portion of the second source/drain pattern 250 is lower than the upper surface of the first source/drain pattern 150.

Accordingly, when the first contact trench RS1 and the second contact trench RS2 are formed by the same the etching process, a bottom surface of the second contact trench RS2 may be formed to be lower than a bottom surface of the first contact trench RS1.

In other words, a second depth L22 between the uppermost surface of the second source/drain pattern 250 and the bottom surface of the second contact trench RS2 may be greater than a first depth L12 between the uppermost surface of the first source/drain pattern 150 and the bottom surface of the first contact trench RS1.

Meanwhile, when the second depth L22 of the second contact trench RS2 is formed excessively deep, the bottom surface of the second contact plug CA2 to be described later has an excessively low height such that a lower surface of the second contact plug CA2 cannot contact the seventh source/drain layer 250c including germanium (Ge) of a high concentration and the first conductivity type impurities (e.g., boron (B)), and accordingly, a problem of increasing the contact resistance may be caused.

However, in some example embodiments according to the present disclosure, as described above, since the thickness of the seventh source/drain layer 250c may be variously changed, even if the bottom surface of the second contact plug CA2 has an excessively low height, the lower surface of the second contact plug CA2 may be in contact with the seventh source/drain layer 250c. In other words, the bottom level of the seventh source/drain layer 250c may be lower than the bottom level of the second contact plug CA2. Accordingly, defects which may be generated in the manufacturing of a semiconductor device, and which may interfere in electrical signal transfer between the second source/drain pattern 250 and the second contact plug CA2 and/or which may increase the contact resistance between them may be decreased.

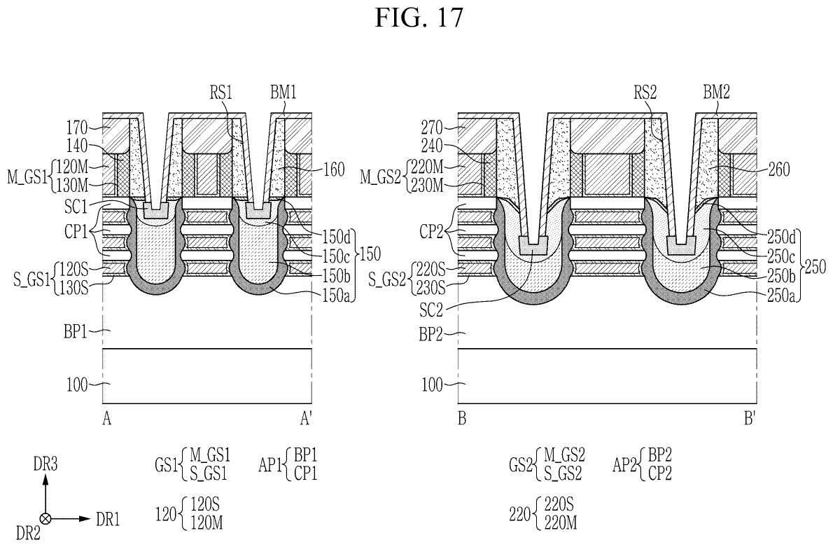

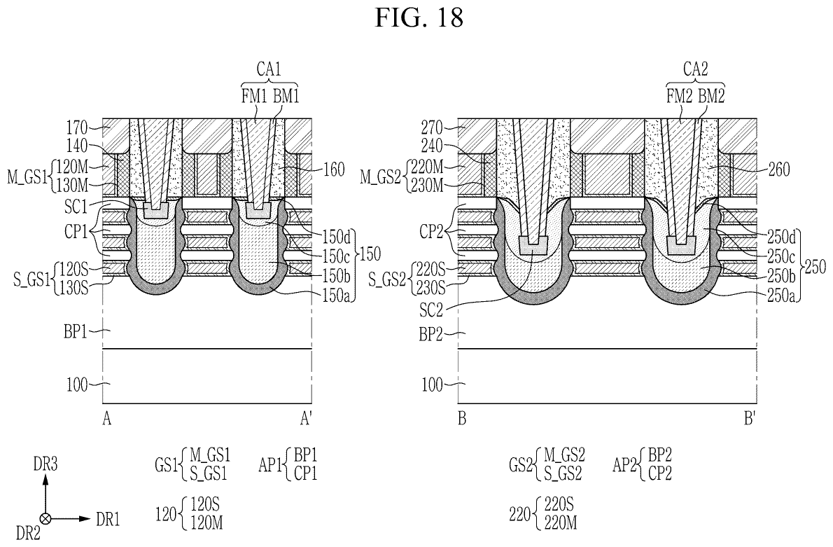

Referring to FIGS. 17 and 18, the first contact plug CA1 penetrating the first interlayer insulating layer 160 and being electrically connected to the first source/drain pattern 150 may be formed. In addition, the second contact plug CA2 penetrating the second interlayer insulating layer 260 and being electrically connected to the second source/drain pattern 250 may be formed.

According to some example embodiments, the first and second barrier patterns BM1 and BM2 and the first and second conductive patterns FM1 and FM2 may be sequentially formed within the first and second contact trenches RS1 and RS2, respectively.

According to some example embodiments, the first and second conductive patterns may be formed along inner sidewalls of the first and second contact trenches RS1 and RS2 through the deposition process. For example, deposition process may include an atomic layer deposition (ALD) process, a physical vapor deposition (PVD), a chemical vapor deposition (CVD) process, or the like. However, example embodiments are not limited thereto.

According to some example embodiments, the first and second conductive patterns may be conformally formed in a line shape along the inner sidewalls of the first and second contact trenches RS1 and RS2. The first and second conductive patterns may be formed with a desired (and/or alternatively predetermined) thickness along the inner sidewalls of the first and second contact trenches RS1 and RS2.

According to some example embodiments, the first and second conductive patterns may include a metal material. For example, the first and second conductive patterns may include titanium (Ti), tantalum (Ta), tungsten (W) or a combination thereof, but the example embodiments are not limited thereto.

According to some example embodiments, at least a partial region among the first and second conductive patterns may be silicidated. Specifically, by performing heat treatment with respect to the first and second conductive patterns, reaction between the semiconductor material configuring the first and second source/drain patterns 150 and 250 and the metal configuring the first and second conductive patterns may be induced.

Accordingly, the first and second silicide patterns SC1 and SC2 covering the first and second source/drain patterns 150 and 250 on bottom surfaces and side walls of the first and second contact trenches RS1 and RS2 may be formed.

According to some example embodiments, when forming the first and second silicide patterns SC1 and SC2, the first and second conductive patterns and the semiconductor regions of the first and second source/drain patterns 150 and 250 may react with each other. At this time, a portion formed along the side walls and bottom surfaces of the first and second contact trenches RS1 and RS2 among the semiconductor regions may be at least partially used for the silicidation reaction.

According to some example embodiments, a portion that does not react with the first and second conductive patterns among the semiconductor regions of the first and second source/drain patterns 150 and 250 may remain on a side surface or a bottom side of the first and second silicide patterns SC1 and SC2, after the first and second silicide patterns SC1 and SC2 are formed.

According to some example embodiments, the first and second silicide patterns SC1 and SC2 may have a desired (and/or alternatively predetermined) thickness.

Meanwhile, when the second depth L22 of the second contact trench RS2 is formed excessively deep, the bottom surface of the second silicide pattern SC2 has an excessively low height such that the seventh source/drain layer 250c including germanium (Ge) of a high concentration and the first conductivity type impurities (e.g., boron) cannot surround the second silicide pattern SC2, and accordingly, defects which may be generated in the manufacturing of a semiconductor device and which may interfere in the electrical signal transfer between the second source/drain pattern 250 and the second contact plug CA2 and/or increase the contact resistance between them may be caused.

However, in some example embodiments according to the present disclosure, as described above, since the thickness of the seventh source/drain layer 250c may be variously changed, even if the bottom surface of the second silicide pattern SC2 has an excessively low height, the seventh source/drain layer 250c may surround the second silicide pattern SC2. Accordingly, defects which may be generated in the manufacturing of a semiconductor device and which may interfere in electrical signal transfer between the second source/drain pattern 250 and the second contact plug CA2 and/or increase the contact resistance between them may be decreased.

According to some example embodiments, the first and second silicide patterns SC1 and SC2 may include metal-silicide. For example, the first and second silicide patterns SC1 and SC2 may include at least one of titanium-silicide, tantalum-silicide, tungsten-silicide, nickel-silicide, and cobalt-silicide. However, example embodiments are not limited thereto.

According to some example embodiments, the first and second silicide patterns SC1 and SC2 may be in direct contact with the first and second barrier patterns BM1 and BM2 that were not silicidated among the first and second conductive patterns.

According to some example embodiments, it is illustrated that the first and second barrier patterns BM1 and BM2 are formed in single layers, but example embodiments are not limited thereto, the first and second barrier patterns BM1 and BM2 may be formed of multiple layers including at least one among a conductive metal or a conductive metal nitride. According to some example embodiments, the first and second conductive patterns may be nitrided such that the first and second barrier patterns BM1 and BM2 may include a metal nitride layer.

According to some example embodiments, the first and second barrier patterns BM1 and BM2 may include conductive metal, conductive metal nitride or a combination thereof. For example, the first and second barrier patterns BM1 and BM2 may include a metal such as titanium (Ti), tantalum (Ta), or tungsten (W). In addition, for example, the first and second barrier patterns BM1 and BM2 may include metal nitride such as titanium nitride (TiN), tantalum nitride (TaN), or tungsten nitride (WN). However, example embodiments are not limited thereto.

According to some example embodiments, the first and second conductive patterns FM1 and FM2 filling the first and second contact trenches RS1 and RS2, respectively, may be formed.

According to some example embodiments, the first and second conductive patterns FM1 and FM2 may extend in the third direction DR3 from an upper surface of the first and second silicide patterns SC1 and SC2 above the first and second source/drain patterns 150 and 250.

Accordingly, a portion of the first and second conductive patterns FM1 and FM2 may be surrounded by the first and second silicide patterns SC1 and SC2. In addition, another portion of the first and second conductive patterns FM1 and FM2 may be located between the first and second barrier patterns BM1 and BM2.

According to some example embodiments, the first and second conductive patterns FM1 and FM2 may be located on the first and second source/drain patterns 150 and 250. The first and second conductive patterns FM1 and FM2 may extend the third direction DR3 above the first and second source/drain patterns 150 and 250. For example, the first and second conductive patterns FM1 and FM2 may extend in the third direction DR3 between the first and second gate spacers 140 and 240 adjacent in the first direction DR1 from the upper surface of the first and second silicide patterns SC1 and SC2.

According to some example embodiments, a portion of the first and second conductive patterns FM1 and FM2 may be located between the first and second gate spacers 140 and 240 located apart in the first direction DR1, respectively. A side surface of a portion of the first and second conductive patterns FM1 and FM2 may be in contact with the first and second barrier patterns BM1 and BM2, but example embodiments are not limited thereto, and another component may be further located between the first and second conductive patterns FM1 and FM2 and the first and second barrier patterns BM1 and BM2.

According to some example embodiments, another portion of the first and second conductive patterns FM1 and FM2 may be located between the first and second sub-gate structures S_GS1 and S_GS2 located apart in the first direction DR1. Another portion of the first and second conductive patterns FM1 and FM2 may be surrounded by the first and second silicide patterns SC1 and SC2, respectively.

According to some example embodiments, the first and second conductive patterns FM1 and FM2 may include a conductive material. For example, the first and second conductive patterns FM1 and FM2 may include at least one of a metal, a metal alloy, a conductive metal nitride, a conductive metal carbide, a conductive metal oxide, a conductive metal carbonitride, and a 2-dimension (2D) material. However, example embodiments are not limited thereto.

According to some example embodiments, the upper surface of the first and second capping layers 170 and 270 may be planarized by using a chemical mechanical polishing (CMP) process. At this time, an upper portion of the first and second capping layers 170 and 270, an upper portion of the first and second interlayer insulating layers 160 and 260, and an upper portion of the first and second conductive patterns FM1 and FM2 may be removed together, but example embodiments are not limited thereto. Accordingly, a semiconductor device according to some example embodiments of the present disclosure may be formed.

As described above, in a semiconductor device according to the present disclosure, a compressive stress applied to a region of the second channel patterns CP2 by the second source/drain pattern 250 may become small due to the thickness of the seventh source/drain layer 250c increasing, since in a long-channel region such as the second region R2 the volumetric ratio of the second contact plug CA2 to the volume of the second source/drain pattern 250 is relatively small, the degradation degree of compressive stress according to the thickness change of the seventh source/drain layer 250c may be small.

In addition, as described above, in a semiconductor device according to the present disclosure, the seventh source/drain layer 250c including germanium (Ge) of a relatively high concentration and impurities (e.g., boron) surrounds the second silicide pattern SC2, and accordingly, the contact resistance between the second source/drain pattern 250 and the second contact plug CA2 may be decreased.

In other words, the upper surface of the second source/drain pattern 250 may be formed to be concave in a long-channel region such as the second region R2 such that the bottom level of the second contact plug CA2 may be formed low, and at this time, by adjusting the thickness of the seventh source/drain layer 250c, the lower surface of the second contact plug CA2 may be brought into contact with the seventh source/drain layer 250c. Accordingly, the contact resistance between the second source/drain pattern 250 and the second contact plug CA2 may be decreased.

While this disclosure has been described in connection with what is presently considered to be practical example embodiments, it is to be understood that the disclosure is not limited to the disclosed example embodiments. On the contrary, it is intended to cover various modifications and equivalent arrangements included within the spirit and scope of the appended claims.

What is claimed is:

1. A semiconductor device, comprising:
a substrate;
a first source/drain pattern and second source/drain pattern spaced apart in a first direction on the substrate;
a height from an upper surface of a central portion of the first source/drain pattern to an upper surface of the substrate in a vertical direction is lower than a height from an upper surface of an edge of the first source/drain pattern to the upper surface of the substrate in the vertical direction, the vertical direction being a direction perpendicular to the upper surface of the substrate;
a plurality of channel patterns connecting between the first source/drain pattern and the second source/drain pattern, and the plurality of channel patterns stacked to be spaced apart from each other;
a gate structure surrounding the plurality of channel patterns and extending in a second direction, the second direction crossing the first direction; and
a contact plug extending in the vertical direction from an upper surface of the first source/drain pattern, and the contact plug connected to the first source/drain pattern,
wherein the first source/drain pattern comprises
a first source/drain layer adjacent to the gate structure,
a second source/drain layer on the first source/drain layer, and
the second source/drain layer comprising first conductivity type impurities, and
a bottom level of the second source/drain layer is lower than a bottom level of the contact plug.

2. The semiconductor device of claim 1, further comprising
a third source/drain layer, and
the third source/drain layer does not comprise the first conductivity type impurities between the first source/drain layer and the second source/drain layer.

3. The semiconductor device of claim 2, wherein
a concentration of germanium (Ge) comprised in at least one among the second source/drain layer or the third source/drain layer is greater than a concentration of germanium (Ge) comprised in the first source/drain layer.

4. The semiconductor device of claim 1, wherein
the contact plug further comprises a silicide pattern, and
the second source/drain layer surrounds the silicide pattern.

5. The semiconductor device of claim 1, wherein the first conductivity type impurities comprise P-type impurities.

6. The semiconductor device of claim 1, wherein a cross-section of the first source/drain layer, according to the first direction and the vertical direction, has a concave upper surface.

7. The semiconductor device of claim 6, wherein an upper surface of the first source/drain pattern, according to a cross-section view in the first direction and the vertical direction, has a slope that increases and then decreases with respect to an upper surface of the substrate from a central portion in the first direction to an edge in the first direction.

8. The semiconductor device of claim 6, wherein an upper surface of the first source/drain pattern, according to a cross-section view in the first direction and the vertical direction, has a slope that increases with respect to an upper surface of the substrate from a central portion in the first direction to an edge in the first direction.

9. A semiconductor device, comprising:
a substrate comprising a first region and a second region;
a first source/drain pattern and a second source/drain pattern spaced apart in a first direction on the first region of the substrate;
a height from an upper surface of a central portion of the first source/drain pattern to an upper surface of the substrate in a vertical direction is higher than, or a same height as, a height from an upper surface of an edge of the first source/drain pattern to the upper surface of the substrate in the vertical direction, the vertical direction being a direction perpendicular to the upper surface of the substrate;
a plurality of first channel patterns connecting between the first source/drain pattern and the second source/drain pattern, and the plurality of first channel patterns stacked to be spaced apart from each other;
a first gate structure surrounding the plurality of first channel patterns and extending in a second direction, the second direction crossing the first direction;
a first contact plug extending in the vertical direction,
the first contact plug penetrating an upper surface of the first source/drain pattern by a first depth, the first depth being a distance from an upper surface of the first source/drain pattern to a bottom surface of the first contact plug, and
the first contact plug connected to the first source/drain pattern;
a third source/drain pattern and a fourth source/drain pattern spaced apart in the first direction on the second region of the substrate;
a height from an upper surface of a central portion of the third source/drain pattern in the vertical direction is lower than a height from the upper surface of an edge of the third source/drain pattern to the upper surface of the substrate in the vertical direction;
a plurality of second channel patterns connecting between the third source/drain pattern and the fourth source/drain pattern, and the plurality of second channel patterns stacked to be spaced apart from each other;
a second gate structure surrounding the second channel patterns and extending in the second direction; and
a second contact plug extending in the vertical direction,
the second contact plug penetrating from an upper surface of the third source/drain pattern by a second depth, the second depth being a distance from an upper surface of the third source/drain pattern to a bottom surface of the second contact plug, and
the second contact plug connected to the third source/drain pattern,
wherein the second depth is greater than the first depth,
the third source/drain pattern comprises
a first source/drain layer adjacent to the second gate structure,
a second source/drain layer on the first source/drain layer, and
the second source/drain layer comprising first conductivity type impurities, and
a bottom level of the second source/drain layer is lower than a bottom level of the second contact plug.

10. The semiconductor device of claim 9, further comprising a third source/drain layer that does not comprise the first conductivity type impurities between the first source/drain layer and the second source/drain layer.

11. The semiconductor device of claim 10, wherein a concentration of germanium (Ge) comprised in at least one among the second source/drain layer or the third source/drain layer is greater than a concentration of germanium (Ge) comprised in the first source/drain layer.

12. The semiconductor device of claim 9, wherein
the second contact plug further comprises a silicide pattern, and
the second source/drain layer surrounds the silicide pattern.

13. The semiconductor device of claim 9, wherein the first conductivity type impurities comprise P-type impurities.

14. The semiconductor device of claim 9, wherein a cross-section of the first source/drain layer, according to the first direction and the vertical direction, has a concave upper surface.

15. A semiconductor device, comprising:
a substrate;
a first source/drain pattern and a second source/drain pattern spaced apart in a first direction on the substrate;
a height from an upper surface of a central portion of the first source/drain pattern to an upper surface of the substrate in a vertical direction is higher than, or a same height as, a height from an upper surface of an edge of the first source/drain pattern to the upper surface of the substrate in the vertical direction, the vertical direction being a direction perpendicular to the upper surface of the substrate;
a plurality of channel patterns connecting between the first source/drain pattern and the second source/drain pattern, and the plurality of channel patterns stacked to be spaced apart from each other;
a gate structure surrounding the plurality of channel patterns and extending in a second direction, the second direction crossing the first direction, and the gate structure having a threshold length; and
a contact plug extending in the vertical direction from an upper surface of the first source/drain pattern, and the contact plug connected to the first source/drain pattern,
wherein the first source/drain pattern comprise
a first source/drain layer adjacent to the gate structure,
a second source/drain layer on the first source/drain layer, and
the second source/drain layer comprising first conductivity type impurities, and
a bottom level of the second source/drain layer is lower than a bottom level of the contact plug.

16. The semiconductor device of claim 15, wherein the threshold length lies in a range of 20 nm to 300 nm.

17. The semiconductor device of claim 15, wherein a distance from the substrate to a lower surface of the second source/drain layer is less than a distance from the substrate to a lower surface of the contact plug.

18. The semiconductor device of claim 15, further comprising a third source/drain layer that does not comprise the first conductivity type impurities between the first source/drain layer and the second source/drain layer.

19. The semiconductor device of claim 18, wherein a concentration of germanium (Ge) comprised in the second source/drain layer is greater than a concentration of germanium (Ge) comprised in the third source/drain layer.

20. The semiconductor device of claim 15, wherein the first conductivity type impurities comprise P-type impurities.
